(19) United States
(12) Patent Application Publication
(10) Pub. No.: US 2026/0075698 A1
(43) Pub. Date: Mar. 12, 2026

(54) AEROSOL GENERATING DEVICE COMPRISING PLURALITY OF CIRCUIT BOARDS

(71) Applicant: KT&G CORPORATION, Daejeon (KR)

(72) Inventors: Jang Won SEO, Gyeonggi-do (KR); Jung Ho KIM, Seoul (KR); Sang Cheol PARK, Gyeonggi-do (KR); Won Kyeong LEE, Gyeonggi-do (KR); Chul Ho JANG, Gyeonggi-do (KR); Jin Chul JUNG, Daejeon (KR)

(73) Assignee: KT&G CORPORATION, Daejeon (KR)

(21) Appl. No.: 19/268,769

(22) Filed: Jul. 14, 2025

(30) Foreign Application Priority Data
Sep. 12, 2024 (KR) 10-2024-0124913
Sep. 12, 2024 (KR) 10-2024-0124915
Nov. 28, 2024 (KR) 10-2024-0173942
Nov. 28, 2024 (KR) 10-2024-0173943

(51) Int. Cl. H05K 1/02; A24F 40/51; A24F 40/57; H05K 1/14

(52) U.S. Cl. CPC H05K 1/0201; A24F 40/51; A24F 40/57; H05K 1/144; H05K 1/145; H05K 2201/066; H05K 2201/093; H05K 2201/10022; H05K 2201/10098; H05K 2201/10151; H05K 2201/10212

(57) ABSTRACT

An aerosol generating device includes a power supply, a first circuit board on which a processor is mounted, a second circuit board, which is arranged spaced apart from the first circuit board and has mounted thereon a radio frequency (RF) signal generation circuit configured to generate an RF signal by using power supplied from the power supply and at least one amplifier configured to amplify the generated RF signal, and a radiating unit configured to heat an aerosol-generating article by radiating the amplified RF signal in the form of electromagnetic waves into an insertion space into which the aerosol-generating article is inserted, wherein the processor is configured to control the RF signal generation circuit and the at least one amplifier.

### CROSS-REFERENCE TO RELATED APPLICATIONS

This application is based on and claims priority under 35 U.S.C. § 119 to Korean Patent Application No. 10-2024-0124913, filed on Sep. 12, 2024, Korean Patent Application No. 10-2024-0124915, filed on Sep. 12, 2024, Korean Patent Application No. 10-2024-0173942, filed on Nov. 28, 2024, Korean Patent Application No. 10-2024-0173943, filed on Nov. 28, 2024, in the Korean Intellectual Property Office, the disclosures of which are incorporated by reference herein in their entirety.

### BACKGROUND

### 1. Field

The disclosure relates to an aerosol generating device including a plurality of circuit boards.

### 2. Description of the Related Art

There is an increasing demand for aerosol generating devices that generate aerosols via non-combustion methods instead of methods of generating aerosols by burning cigarettes. The aerosol generating device refers to, for example, a device that performs functions of generating aerosol from an aerosol-generating material in a non-combustion method and providing the aerosol to a user or generating aerosol having flavors by passing a vapor generated from the aerosol-generating material through flavor media.

The aerosol generating device may heat the aerosol-generating material in various manners, such as resistive heating, inductive heating, ultrasonic transducer-based heating, etc. In addition to the above-described methods, research is also being conducted on an aerosol generating device that may heat an aerosol-generating material by using the principle of dielectric heating. However, implementing of dielectric heating may require new circuit elements that were not included in existing aerosol generating devices, and may require techniques for appropriately distributing and/or arranging the new circuit elements within at least one circuit board.

### SUMMARY

Various embodiments relate to an aerosol generating device including a plurality of circuit boards. Since circuit elements have different operating conditions and/or operating characteristics, a type of circuit board appropriate for each circuit element may vary. In addition, since circuit elements mounted on a same circuit board may influence each other, a desirable layout in consideration of each operating condition and/or operating characteristic may be required. Various embodiments may provide techniques for distributing and/or arranging circuit elements for implementing dielectric heating within at least one circuit board in a suitable manner.

Problems to be solved through embodiments of the disclosure are not limited to the above-described problems, and problems not mentioned may be clearly understood by one of ordinary skill in the art to which the embodiments belong from the description and accompanying drawings.

Additional aspects will be set forth in part in the description which follows and, in part, will be apparent from the description, or may be learned by practice of the presented embodiments of the disclosure.

An aerosol generating device according to an embodiment includes a power supply, a first circuit board on which a processor is mounted, a second circuit board, which is arranged spaced apart from the first circuit board and has mounted thereon a radio frequency (RF) signal generation circuit configured to generate an RF signal by using power supplied from the power supply and at least one amplifier configured to amplify the generated RF signal, and a radiating unit configured to heat an aerosol-generating article by radiating the amplified RF signal in the form of electromagnetic waves into an insertion space into which the aerosol-generating article is inserted, wherein the processor is configured to control the RF signal generation circuit and the at least one amplifier.

In an embodiment, a first region in which the RF signal generation circuit is mounted and a second region in which the at least one amplifier is mounted may be physically separated from each other within the second circuit board.

In an embodiment, the RF signal generation circuit and the at least one amplifier are respectively positioned close to, from among edges or corners of the second circuit board, two edges or corners of the second circuit board, the two edges or corners being opposite each other with respect to a center of the second circuit board.

In an embodiment, the second circuit board may include a first ground connected to the RF signal generation circuit and a second ground disposed separately from the first ground and connected to the at least one amplifier, and the first ground and the second ground may be electrically connected to each other at a single point by a noise reduction element.

The noise reduction element may include at least one of a zero-ohm resistor and a bead.

When the second circuit board includes a multilayer circuit board including at least one ground layer therein, the first ground and the second ground may be respectively disposed in physically separated areas within the at least one ground layer.

In an embodiment, the at least one amplifier may include a drive amplifier configured to amplify a level of the generated RF signal, and a power amplifier configured to amplify power of the RF signal received from the drive amplifier.

The aerosol generating device may further include a temperature sensing circuit mounted on the second circuit board, wherein the temperature sensing circuit is positioned adjacent to the power amplifier.

The processor may be further configured to stop operation of at least one of the RF signal generation circuit and the at least one amplifier in response to determining that a temperature measured by the temperature sensing circuit exceeds a preset threshold value.

In an embodiment, the aerosol generating device may further include a heat dissipation unit configured to effectively dissipate or disperse heat generated from the second circuit board to minimize transfer of heat generated from the second circuit board to the power supply.

The second circuit board may be positioned so as not to overlap the power supply in any of left-right, front-back, and up-down directions, and the heat dissipation unit may be arranged in contact with or adjacent to at least one surface of the second circuit board.

In an embodiment, the aerosol generating device may further include a directional coupler configured to separately receive the amplified RF signal and reflected electromagnetic waves radiated by the radiating unit and then reflected from the insertion space.

The directional coupler and the at least one amplifier may be respectively positioned close to two edges or corners which are opposite to each other with respect to a center of the second circuit board among edges or corners of the second circuit board.

The directional coupler and the at least one amplifier may be disposed on different surfaces of the second circuit board.

In an embodiment, the aerosol generating device may further include at least one power conversion circuit mounted on the first circuit board and configured to convert power supplied from the power supply into power suitable for each of the processor, the RF signal generation circuit, and the at least one amplifier, wherein an area in which a digital circuit including the processor is mounted and an area in which an analog circuit including the at least one power conversion circuit is mounted are electrically and physically separated from each other within the first circuit board.

According to another embodiment, an aerosol generating device includes a power supply, a first circuit board having mounted thereon a processor and an RF signal generation circuit configured to generate an RF signal using power supplied from the power supply, a second circuit board directly mounted on a surface of the first circuit board and having mounted thereon at least one amplifier configured to amplify the generated RF signal, and a radiating unit configured to heat an aerosol-generating article by radiating the amplified RF signal in the form of electromagnetic waves into an insertion space into which the aerosol-generating article is inserted, wherein the processor may be configured to control the RF signal generation circuit and the at least one amplifier, and a permittivity of the second circuit board may be lower than a permittivity of the first circuit board.

In an embodiment, the power supply and the first circuit board may be arranged parallel to each other, the first circuit board may include a portion extending beyond one end of the power supply, and the second circuit board may be mounted on a surface of the extending portion.

In an embodiment, the second circuit board may be mounted on, from among opposite surfaces of the first circuit board, a surface of the first circuit board, which does not face the power supply.

In an embodiment, the aerosol generating device may further include a heat dissipation unit to effectively dissipate or disperse heat generated from the second circuit board so as to minimize transfer, to the power supply, of heat generated from the second circuit board.

The second circuit board may be positioned so as not to overlap the power supply in any of left-right, front-back, and up-down directions, and the heat dissipation unit may be arranged in contact with or adjacent to at least one surface of the second circuit board.

In an embodiment, the aerosol generating device may further include at least one power conversion circuit mounted on the first circuit board and configured to convert power supplied from the power supply into power suitable for each of the processor, the RF signal generation circuit, and the at least one amplifier, wherein a first region in which the processor and the RF signal generation circuit are mounted and a second region in which the at least one power conversion circuit is mounted may be physically separated from each other within the first circuit board.

The first circuit board may include a first ground connected to the processor and the RF signal generation circuit and a second ground disposed separately from the first ground and connected to the at least one power conversion circuit, and the first ground and the second ground may be electrically connected to each other at a single point by a noise reduction element.

The noise reduction element may include at least one of a zero-ohm resistor and a bead.

When the first circuit board is a multilayer circuit board including at least one ground layer therein, the first ground and the second ground may be respectively disposed in physically separated areas within the at least one ground layer.

The second circuit board may further include a third ground connected to the at least one amplifier, and the third ground may be directly connected to the second ground, but may be connected to the first ground through the noise reduction element.

The aerosol generating device may further include a shielding part arranged on the second circuit board and arranged to surround the at least one amplifier, and the shielding part may be connected to the third ground.

In an embodiment, the at least one amplifier may include a drive amplifier configured to amplify a level of the generated RF signal and a power amplifier configured to amplify power of an RF signal received from the drive amplifier.

The aerosol generating device may further include a temperature sensing circuit mounted on the second circuit board, wherein the temperature sensing circuit may be positioned adjacent to the power amplifier.

The processor may be further configured to stop operation of at least one of the RF signal generation circuit and the at least one amplifier in response to determining that a temperature measured by the temperature sensing circuit exceeds a preset threshold.

In an embodiment, the aerosol generating device may further include a directional coupler that separates and receives the amplified RF signal and reflected electromagnetic waves reflected from the insertion space after being radiated by the radiating unit, wherein the directional coupler and the at least one amplifier may be respectively disposed close to two edges or corners that are opposite to each other with respect to a center of the second circuit board among edges or corners of the second circuit board.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an aerosol generating device according to an embodiment;

FIG. 2 is a schematic cross-sectional view of an aerosol generating device according to an embodiment;

FIG. 3 is a diagram illustrating one surface of a first circuit board according to an embodiment;

FIG. 4 is a diagram illustrating a ground layer of a first circuit board according to an embodiment;

FIG. 5 is a diagram illustrating one surface of a second circuit board according to an embodiment;

FIG. 6 is a diagram illustrating a ground layer of a second circuit board according to an embodiment;

FIG. 7 is a diagram for describing an arrangement of a directional coupler according to an embodiment;

FIG. 8 is a schematic cross-sectional view of an aerosol generating device according to another embodiment;

FIG. 9 is a diagram illustrating one surface of each of a first circuit board and a second circuit board according to an embodiment;

FIG. 10 is a diagram illustrating a ground layer of a first circuit board according to an embodiment;

FIG. 11 is a diagram illustrating a ground layer of a second circuit board according to an embodiment; and

FIG. 12 is a diagram for describing a shielding part according to an embodiment.

### DETAILED DESCRIPTION

Hereinafter, embodiments will be described in detail with reference to the accompanying drawings, and the same or similar components will be assigned the same reference numerals regardless of the reference numerals in the drawings, and the same descriptions thereof will be omitted. With regard to the description of the drawings, like reference numerals may be used to represent like or related elements.

The suffixes “module”, “unit”, “-er”, and “-or” for the components used in the following description are given or used interchangeably by considering only the ease of writing the description, and do not have distinct meanings or roles in themselves. The suffix “module” or “unit”, as used herein, may include a unit implemented as hardware, software, or firmware. For example, the suffix “module” or “unit” may be interchangeably used with the term a “logic”, a “logical block”, a “component”, or a “circuit”. The “module” or “unit” may be an integrally formed component, a minimum unit of the component performing one or more functions, or a part of the minimum unit. For example, the “module” or “unit” may be implemented in the form of an application-specific integrated circuit (ASIC).

In addition, when describing the embodiments of the disclosure, the detailed description of the related known art, which may obscure the subject matter of the embodiments, may be omitted. Also, the accompanying drawings are only intended to facilitate understanding of the embodiments described herein, and the spirit of the disclosure is not limited by the accompanying drawings and should be understood to include all changes, equivalents or alternatives included in the spirit and scope of the disclosure.

Although the terms first, second, etc. may be used herein to describe various elements or components, these elements or components should not be limited by these terms. These terms are only used to distinguish one element or component from another element or component.

When an element is referred to as being “connected to” or “coupled to” another element, it may be directly connected or coupled to the other element or intervening elements may be present. In contrast, when an element is referred to as being “directly connected to” or “directly coupled to” another element, there are no intervening elements present.

The singular forms are intended to include the plural forms as well, unless the context clearly indicates otherwise.

Various embodiments of the present disclosure may be implemented as software including one or more instructions stored in a storage medium (e.g., a memory) readable by a machine (e.g., an aerosol generating device 1). For example, a processor (e.g., the processor 170) of the machine (e.g., the aerosol generating device 1) may call at least one instruction among one or more instructions stored from the storage medium and execute the at least one instruction. This makes it possible for the machine to be operated to perform at least one function according to the called at least one instruction. Examples of the one or more instructions may include codes created by a compiler, or codes executable by an interpreter. A machine-readable storage medium may be provided as a non-transitory storage medium. The ‘non-transitory storage medium’ is a tangible device and only means that it does not contain a signal (e.g., electromagnetic waves). This term does not distinguish a case in which data is stored semi-permanently in a storage medium from a case in which data is temporarily stored.

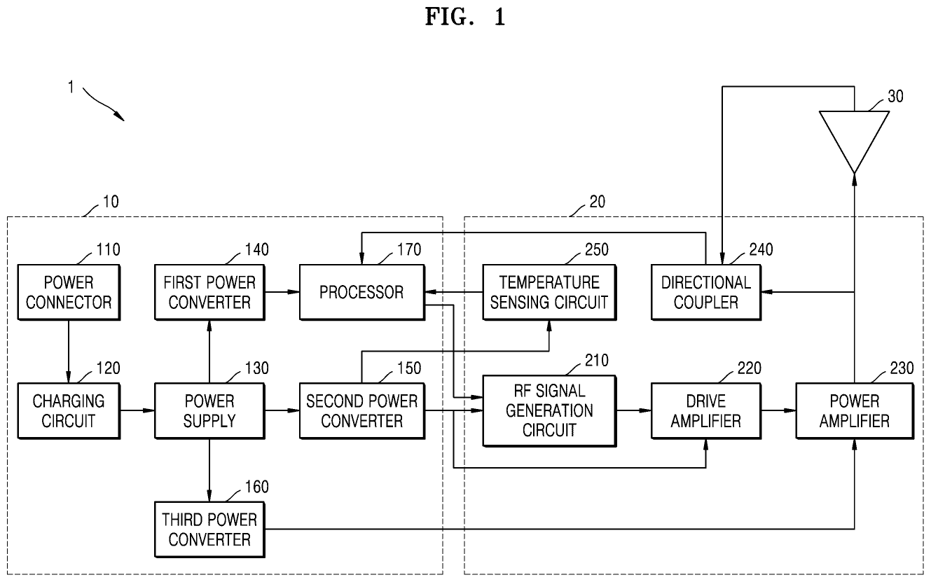

FIG. 1 is a block diagram of an aerosol generating device 1 according to an embodiment.

According to an embodiment, the aerosol generating device 1 may include a control unit 10, a source unit 20, and a radiating unit 30. The control unit 10 may refer to a circuit for controlling the basic operation of the aerosol generating device 1. The source unit 20 may refer to a circuit for generating a radio frequency (RF) signal under the control by the control unit 10. The radiating unit 30 may be a device for radiating an RF signal generated by the source unit 20 in the form of electromagnetic waves into a space into which an aerosol-generating article is inserted (hereinafter, “insertion space”). Charges or ions of a dielectric (e.g., glycerin) included in an aerosol-generating article may vibrate or rotate due to radiated electromagnetic waves (e.g., RF signals), and the aerosol-generating article may be heated as the dielectric generates heat due to frictional heat generated in the process of the charges or ions vibrating or rotating. In other words, the aerosol generating device 1 may be a device that generates an aerosol by heating an aerosol-generating article in a dielectric heating manner.

In an embodiment, the control unit 10 may include a power connector 110, a charging circuit 120, a power supply 130, a first power converter 140, a second power converter 150, a third power converter 160, and/or a processor 170. Additionally, the source unit 20 may include an RF signal generation circuit 210, a drive amplifier 220, a power amplifier 230, a directional coupler 240, and/or a temperature sensing circuit 250. However, it will be understood by those skilled in the art related to the present embodiment that some of the components illustrated in FIG. 1 may be omitted or new components may be added according to the design of the aerosol generating device 1.

The power connector 110 may refer to a physical connection device that is electrically connected to an electronic device or system (e.g., an external power supply) outside the aerosol generating device 1 and used to transmit and receive power. For example, the power connector 110 may receive power from an external power supply and transmit the received power to a component requiring charging (e.g., the power supply 130). The power connector 110 may also provide a path for data transmission. In this case, the power connector 110 may be referred to as a data and power connector. The aerosol generating device 1 may transmit and receive data to or from an external electronic device or system (e.g., a smartphone, a computer, etc.) through the power connector 110. The power connector 110 may include a Universal Serial Bus (USB) power connector, a direct current (DC) power connector, etc. In an example, the power connector 110 may include, but is not limited to, a USB-C type connector capable of supplying 9 V of direct current (DC) voltage at a current of 1 A. The power connector 110 may also include an interface for transmitting and receiving power wirelessly.

The charging circuit 120 may refer to a circuit for charging the power supply 130. The charging circuit 120 may charge the power supply 130 by using power transmitted from the power connector 110. In an example, the charging circuit 120 may be implemented as a charger IC, which is an integrated circuit (IC) that performs functions for efficiently and safely charging the power supply 130. The charging circuit 120 may monitor the charging status of the power supply 130 or optimize the charging process by monitoring the voltage, current, and/or temperature of the power supply 130. For example, the charging circuit 120 may detect the status of the power supply 130 and prevent overcharging or overdischarging by providing an appropriate charging voltage and current.

The power supply 130 may supply power for the operation of the aerosol generating device 1. The power supply 130 may include one or more rechargeable batteries. The power supply 130 may supply power to the radiating unit 30 such that the radiating unit 30 may radiate electromagnetic waves (e.g., RF signals) into the insertion space to heat an aerosol-generating article. Here, power supply to the radiating unit 30 may indicate power supply to the source unit 20. Additionally, the power supply 130 may supply power required for the operation of the processor 170, the RF signal generation circuit 210, the drive amplifier 220, the power amplifier 230, the temperature sensing circuit 250, etc. In an example, the power supply 130 may include, but is not limited to, a lithium polymer (LiPoly) battery. The power supply 130 may be a replaceable type (separated type) battery (hereinafter, a removable battery). The removable battery may be mounted in a battery holder provided within the aerosol generating device 1 or removed from the battery holder. The removable battery may be charged in a wired manner and/or wirelessly.

The aerosol generating device 1 may include a power conversion circuit for converting power supplied from the power supply 130 into power (e.g., voltage and/or current) suitable for other components. The power conversion circuit may include at least one of a buck converter, a buck-boost converter, a boost converter, a Zener diode, and a low-dropout (LDO) regulator. Additionally, the power conversion circuit may include a DC/AC converter (e.g., an inverter) as required.

In an example, the aerosol generating device 1 may include the first power converter 140, the second power converter 150, and the third power converter 160. The first power converter 140 may be an LDO regulator for supplying power (e.g., a DC of 3.3 V) suitable for the processor 170, the second power converter 150 may be a buck-boost converter for supplying power (e.g., a DC of 5 V) suitable for the temperature sensing circuit 250, the RF signal generation circuit 210, and the drive amplifier 220, and the third power converter 160 may be a boost converter for supplying power (e.g., a DC of 12 V/25 W) suitable for the power amplifier 230.

However, the first power converter 140, the second power converter 150, and the third power converter 160 are not limited to the examples described above and may include other types of power conversion circuits. Additionally, although FIG. 1 illustrates the aerosol generating device 1 including three power converters, the aerosol generating device 1 may include more than three power converters or may include fewer power converters. In an example, at least some of the first power converter 140, the second power converter 150, and the third power converter 160 may be integrated into a single power converter.

The processor 170 may control the overall operation of the aerosol generating device 1. For example, the processor 170 may directly or indirectly control charging and discharging of the power supply 130 by using the charging circuit 120. Additionally, the processor 170 may control the voltage and/or current output by a power conversion circuit by controlling the frequency and/or duty ratio of a current pulse input to at least one switching element of the power conversion circuit. In addition to the components described above, the processor 170 may also control the overall operation of other components to be described later.

The processor 170 may be implemented as an array of multiple logic gates, or may be implemented as a combination of a general-purpose microcontroller unit (MCU) (or microprocessor) and a memory storing a program that may be executed in the MCU. Additionally, it will be understood by those skilled in the art that the processor 170 may be implemented in other forms of hardware.

The RF signal generation circuit 210 may generate an RF signal based on power delivered from the power supply 130 or the second power converter 150. An RF signal may refer to a signal having a frequency within a range of about 300 MHz to about 300 GHz. In an example, the RF signal may have a frequency of about 1 GHz to about 100 GHz. Additionally, the RF signal may have a frequency in the Industrial Scientific and Medical equipment (ISM) band, for example, 915 MHz, 2.45 GHZ, and/or 5.8 GHz.

The RF signal generation circuit 210 may include a voltage-controlled oscillator (VCO) that generates an RF signal having a different frequency depending on an input voltage. The RF signal generation circuit 210 may receive a control signal (e.g., a DC signal) from the processor 170 and generate an RF signal having a frequency corresponding to the received control signal. The processor 170 may store a control signal corresponding to a desired frequency in the form of a look-up table, or calculate a control signal corresponding to a desired frequency in real time through at least one operation.

In an example, the aerosol generating device 1 may further include a digital to analog converter (D/A converter) for converting a digital control signal output from the processor 170 into an analog control signal. The RF signal generation circuit 210 may receive the analog control signal and generate an RF signal having a frequency corresponding to the received analog control signal.

The drive amplifier 220 may amplify the RF signal generated by the RF signal generation circuit 210. For example, the drive amplifier 220 may provide an input signal suitable for a component of a next stage (e.g., the power amplifier 230) by amplifying the signal level (e.g., amplitude) of the RF signal. The drive amplifier 220 may minimize signal distortion by maintaining high linearity. However, since the drive amplifier 220 is an amplifier focused on increasing the signal level, the drive amplifier 220 may provide relatively low output power.

The power amplifier 230 may amplify power of an RF signal received from the drive amplifier 220. The power amplifier 230 may be an amplifier focused on providing sufficient power to a final output device (e.g., the radiating unit 30). For example, the power amplifier 230 may provide a high-power RF signal to the radiating unit 30 so that the radiating unit 30 may radiate electromagnetic waves into the insertion space to heat an aerosol-generating article. The power amplifier 230 may perform an amplification operation by using power received through the third power converter 160 that provides higher power and/or voltage than the second power converter 150.

The drive amplifier 220 and the power amplifier 230 may include transistors such as a bipolar junction transistor (BJT), a field effect transistor (FET), or a vacuum tube. In an example, the drive amplifier 220 and the power amplifier 230 may be, but are not limited to, gallium nitride (GaN) transistors configured to handle high efficiency, high speed, and high voltage. The drive amplifier 220 and the power amplifier 230 may also include an operational amplifier.

In FIG. 1, the drive amplifier 220 and the power amplifier 230 are illustrated as individual amplifiers, but the drive amplifier 220 and the power amplifier 230 may be integrated into a single amplifier. Additionally, the drive amplifier 220 and/or the power amplifier 230 may be configured as a series connection, a parallel connection, and/or a combination thereof of a plurality of amplifiers.

The radiating unit 30 may include at least one antenna for radiating electromagnetic waves into space. At least one antenna may have a size and shape suitable for the size and shape of an aerosol-generating article. For example, if the aerosol-generating article is cylindrical in shape, at least one antenna may be tubular surrounding the aerosol-generating article that is cylindrical. Here, the shape of the antenna being tubular may indicate that the overall shape of the antenna is tubular. In other words, if the antenna is formed of a metal (e.g. SUS) track, this may indicate that the overall shape of the entire track is tubular. The shape of at least one antenna is not limited to the examples described above and may include various shapes such as a flat plate shape, a curved plate shape, etc.

The radiating unit 30 may heat the aerosol-generating article by radiating electromagnetic waves (e.g., an amplified RF signal or a transmitted RF signal) into the insertion space. For the heating efficiency of the aerosol generating article to be maximized, resonance of electromagnetic waves is to occur within the insertion space. The resonance conditions (e.g., resonant frequency) of the insertion space may vary depending on the amount of dielectric contained in the inserted aerosol-generating article. The processor 170 may control the frequency of an RF signal generated by the RF signal generation circuit 210 to correspond to or be close to the resonance condition of the insertion space by adjusting a control signal input to the RF signal generation circuit 210. The processor 170 may use the directional coupler 240 to obtain information about the resonance conditions of the insertion space.

The directional coupler 240 may refer to a passive element having a waveguide structure that separates an incident wave and a reflected wave from each other. The directional coupler 240 may receive an RF signal transmitted from the power amplifier 230 toward the radiating unit 30 and electromagnetic waves reflected from the insertion space after they are radiated by the radiating unit 30. The directional coupler 240 may separate the transmitted RF signal and the reflected electromagnetic waves, and provide them to the processor 170.

In an example, the aerosol generating device 1 may further include an analog to digital converter (A/D converter) for converting an analog output of the directional coupler 240 into a digital output. The A/D converter may be built into the processor 170 or may exist as a separate component outside the processor 170. The processor 170 may analyze the characteristics (e.g., current, voltage, power, phase, and/or frequency) of the transmitted RF signal and the characteristics (e.g., current, voltage, power, phase, and/or frequency) of the reflected electromagnetic waves by monitoring the output of the directional coupler 240.

The processor 170 may determine whether the operation of the source unit 20 is being performed as intended, based on the characteristics of the transmitted RF signal. Additionally, the characteristics of the transmitted RF signal may be used to determine the heating efficiency of the source unit 20 or the radiating unit 30, together with the characteristics of the reflected electromagnetic wave. The processor 170 may control the source unit 20 such that the heating efficiency of the source unit 20 or the radiating unit 30 is maximized. For example, the processor 170 may adjust the frequency of an RF signal generated by the RF signal generation circuit 210 such that the power of the reflected electromagnetic waves is minimized. Minimizing the power of the reflected electromagnetic waves may indicate that the frequency of the RF signal is closer to the resonance conditions of the insertion space. The characteristics of the transmitted RF signal may provide a criterion for whether the power of the reflected electromagnetic waves is minimized.

Since resonance of electromagnetic waves may occur in the insertion space depending on the frequency of the RF signal, the insertion space may be referred to as a resonant section. At least a portion of the insertion space may be surrounded by at least one shielding member to prevent electromagnetic waves from leaking outside the aerosol generating device 1. In an embodiment, the insertion space may further include a physical structure to ensure that the resonance conditions are within a range controllable by the processor 170. The physical structure may include at least one conductor, and the resonance conditions of the insertion space may vary depending on the arrangement, thickness, and length of the conductor. Additionally, the physical structure may include a space for accommodating a dielectric having low electromagnetic absorption, separate from the dielectric contained in the aerosol-generating article. A dielectric with low electromagnetic absorption may change the resonant frequency of the entire resonant section without absorbing the energy that are to be transferred to the heated material. Accordingly, even if the resonant section is reduced in size, the resonance conditions may be determined within a range controllable by the processor 170.

The temperature sensing circuit 250 may be arranged in contact with or adjacent to components included in the source unit 20 to measure the temperature of the source unit 20. For example, the temperature sensing circuit 250 may be arranged in contact with or adjacent to at least one of the RF signal generation circuit 210, the drive amplifier 220, and the power amplifier 230. Heat may be generated due to limited efficiency in the process of generating and/or amplifying RF signals, and if excessive heat is generated, this heat may have a negative impact on components included in the source unit 20 or other components included in the aerosol generating device 1. The temperature measured by the temperature sensing circuit 250 may be used to prevent overheating of the source unit 20.

The processor 170 may receive the temperature (or a value corresponding to the temperature) measured from the temperature sensing circuit 250, and if it is determined that the source unit 20 is overheated, the processor 70 may stop the operation of the source unit 20. For example, the processor 170 may stop the operation of the source unit 20 by cutting off the power supply to the source unit 20 or transmitting a control signal. Hereinafter, the term ‘power supply’ to the source unit 20 is used to indicate controlling whether the source unit 20 operates.

The temperature sensing circuit 250 may include at least one temperature sensor among a thermocouple, a resistance temperature detector (RTD), a thermistor, a semiconductor temperature sensor, and an optical temperature sensor. In an example, the temperature sensing circuit 250 may be implemented as a chip-type sensor (e.g., a negative temperature coefficient (NTC) sensor) to minimize the area occupied, but is not limited thereto.

The aerosol generating device 1 may include other components in addition to the components illustrated in FIG. 1. For example, the aerosol generating device 1 may further include a sensor unit, an output unit, an input unit, a communication unit, and a memory. In addition, if the aerosol generating device 1 is a hybrid type device that uses both an aerosol-generating article and a cartridge, the aerosol generating device 1 may further include a cartridge heater. The cartridge heater may receive power from the power supply 130 to heat a medium and/or an aerosol-generating material within the cartridge.

According to an embodiment, the sensor unit may detect the status of the aerosol generating device 1 or the status around the aerosol generating device 1 and transmit the detected information to the processor 170. For example, the sensor unit may include a temperature sensor, a puff sensor, an insertion detection sensor, a reuse detection sensor, an overly moist detection sensor, a cigarette identification sensor, a cartridge detection sensor, a cap detection sensor, and/or a motion detection sensor. The sensor unit may further include various sensors, such as a liquid remaining amount sensor for detecting the remaining liquid amount of the cartridge, and an immersion sensor for detecting immersion of the aerosol generating device 1.

In an embodiment, the temperature sensor may detect the temperature of the insertion space or the aerosol-generating article. The temperature sensor may be positioned in contact with or adjacent to the insertion space or the aerosol-generating article to directly measure the temperature of the insertion space or the aerosol-generating article. Additionally, the temperature sensor may be positioned to be spaced apart from the insertion space or the aerosol-generating article to indirectly measure the temperature of the insertion space or the aerosol-generating article (e.g., in a non-contact manner). In an example, the temperature sensor may include an optical temperature sensor (e.g., an infrared temperature sensor).

In an embodiment, the temperature sensor may detect the temperature of the power supply 130. The temperature sensor may be arranged adjacent to the power supply 130. For example, the temperature sensor may be attached to one surface of the power supply 130 (e.g., a battery) and/or mounted on one surface of a printed circuit board. For example, the aerosol generating device 1 may include a protection circuit module (PCM), and the temperature sensor may be positioned adjacent to the power supply 130 together with the PCM.

According to an embodiment, the temperature sensor may be arranged inside the housing (not shown) of the aerosol generating device 1 to detect the temperature inside the housing (not shown).

In an embodiment, the puff sensor may detect a user's puff.

As an example, the puff sensor may include a pressure sensor. The pressure sensor may output a signal corresponding to the internal pressure of the aerosol generating device 1, and the processor 170 may detect a user's puff based on the signal corresponding to the internal pressure. The internal pressure of the aerosol generating device 1 may correspond to pressure of an airflow path on which gas flows. The puff sensor may be disposed to correspond to the airflow path, through which gas flows, in the aerosol generating device 1.

In another example, the puff sensor may include a temperature sensor. When a user puffs, a temporary temperature drop may occur in the airflow path, the insertion space, the aerosol generating article, etc. The processor 170 may detect the user's puff based on a signal corresponding to the temperature of an airflow path, etc. output from a temperature sensor.

In another example, the puff sensor may include both a pressure sensor and a temperature sensor. In this case, the temperature sensor may measure the temperature which is used to correct the internal pressure measured by the pressure sensor. For example, the puff sensor may correct a signal corresponding to internal pressure based on a temperature measured by the temperature sensor and output the corrected signal. In another example, the puff sensor may output a signal corresponding to a temperature measured by the temperature sensor and a signal corresponding to the internal pressure measured by the puff sensor. In this case, the processor 170 may receive the signals and correct the signal corresponding to the internal pressure, based on the signal corresponding to the temperature.

In another example, the puff sensor may include a capacitance-based sensor. In the disclosure, the capacitance-based sensor may also be referred to as a capacitive sensor. When a user puffs, temperature changes and/or aerosol flow may occur within the insertion space, thereby changing the permittivity within the insertion space. The processor 170 may detect the user's puff based on a signal corresponding to the permittivity inside the insertion space output from the capacitive sensor.

The puff sensor is not limited to the examples described above and may be implemented with various sensors to detect the user's puff.

In an embodiment, the insertion detection sensor may detect insertion and/or removal of an aerosol-generating article. The insertion detection sensor may be installed around the insertion space.

As an example, the insertion detection sensor may include a capacitive sensor. The capacitive sensor may include at least one conductor, wherein the at least one conductor may be positioned adjacent to the insertion space. When an aerosol generating article is inserted or removed within the insertion space, the permittivity around the conductor may change. The processor 170 may detect insertion and/or removal of an aerosol-generating article based on a signal corresponding to the permittivity inside the insertion space output from the capacitive sensor.

In another example, the insertion detection sensor may include an inductive sensor. The inductive sensor may include at least one coil, wherein the at least one coil may be positioned adjacent to the insertion space. When an aerosol-generating article (e.g., a wrapper for the aerosol-generating article) contains a conductor, a change in the magnetic field may occur around the current-carrying coil when the aerosol-generating article is inserted into or removed from the insertion space. The processor 170 may detect insertion and/or removal of an aerosol-generating article including a conductor based on characteristics of a current output from or detected by an inductive sensor (e.g., frequency of an alternating current, current value, voltage value, inductance value, impedance value, etc.). Alternatively, the aerosol-generating article (e.g., the medium portion of the aerosol-generating article) may include a susceptor (e.g., SUS). Even in this case, a change in the magnetic field around the coil may occur based on the insertion or removal of a susceptor or the like within the insertion space, and the processor 170 may also detect the insertion and/or removal of the aerosol-generating article based on the characteristics of the current of the inductive sensor.

The insertion detection sensor is not limited to the examples described above and may be implemented using various sensors (e.g., proximity sensors, etc.) for detecting insertion and/or removal of an aerosol-generating article. Additionally, the insertion detection sensor may include any combination of the examples described above. In an embodiment, the insertion detection sensor may include a switch or the like for detecting compression by an aerosol-generating article.

In an embodiment, the reuse detection sensor may detect whether an aerosol-generating article has been reused. As an example, the reuse detection sensor may be a color sensor for detecting the color of the aerosol generating article. When the aerosol-generating article is used by a user, a change in color of a portion of the wrapper surrounding the outside of the aerosol-generating article may occur due to the generated aerosol or heating. The color sensor may output a signal corresponding to optical characteristics (e.g., wavelength of light) corresponding to the color of the wrapper based on light reflected from the wrapper. The processor 170 may determine that the aerosol-generating article inserted into the insertion space has already been used if a change in color of a portion of the wrapper is detected.

In an embodiment, the overly moist detection sensor may detect whether the aerosol-generating article is overly moist. For example, the overly moist detection sensor may include a capacitive sensor. The capacitive sensor may include at least one conductor positioned adjacent to the insertion space. The processor 170 may detect whether the aerosol-generating article is overly moist, based on the level of a signal corresponding to a permittivity or the like output from the capacitive sensor. For example, the processor 170 may determine a level range within which the level of the signal is included, based on a look-up table, and determine the moisture content of the aerosol-generating article based on the determined level range.

In an embodiment, the cigarette identification sensor may detect whether the aerosol-generating article is authentic and/or detect the type of the aerosol-generating article.

As an example, the cigarette identification sensor may include an optical sensor for detecting an identification material (or identification tag) located on an outer surface of an aerosol-generating article (e.g., a wrapper). The optical sensor may irradiate light toward the identification material (or identification mark) of the aerosol-generating article and detect, based on the reflected light, the authenticity and/or type of the aerosol-generating article. For example, the identification material may include a material that emits light of a particular wavelength, based on the irradiated light. The processor 170 may detect whether the aerosol-generating article is authentic and/or the type of the article based on the range of the wavelength.

In another example, the cigarette identification sensor may include a capacitive sensor. Depending on the type of aerosol generating article inserted into the insertion space, the permittivity inside the insertion space may vary. The processor 170 may detect whether the aerosol generating article is authentic and/or the type thereof based on a signal corresponding to the permittivity inside the insertion space output from the capacitive sensor.

In another example, the cigarette identification sensor may include an inductive sensor. When a conductor is included in a wrapper and/or interior (e.g., medium portion) of an aerosol-generating article inserted into the insertion space, the characteristics of the current detected by the inductive sensor (e.g., frequency of AC current, current value, voltage value, inductance value, impedance value, etc.) may differ depending on the type of the aerosol-generating article inserted into the insertion space. The processor 170 may detect whether the inserted aerosol-generating article is authentic and/or the type thereof based on the characteristics of the current output from or detected by the inductive sensor.

The cigarette identification sensor is not limited to the examples described above and may be implemented using various sensors to detect whether the aerosol-generating article is authentic and/or to detect the type of the aerosol-generating article. Additionally, the cigarette identification sensor may include any combination of the examples described above.

In an embodiment, the cartridge detection sensor may detect mounting and/or removal of a cartridge. For example, the cartridge detection sensor may include an inductive sensor, a capacitive sensor, a resistive sensor, a hall sensor (hall IC) and/or an optical sensor.

In an embodiment, the cap detection sensor may detect attachment and/or removal of a cap. For example, the cap detection sensor may include an inductive sensor, a capacitive sensor, a resistive sensor, a contact sensor, a hall sensor (hall IC) and/or an optical sensor. The cap may include a structure that covers at least a portion of a cartridge mounted or inserted into the aerosol generating device 1, or covers at least a portion of the housing of the aerosol generating device 1. The cap detection sensor may output a signal corresponding to the mounting or removal of the cap when the cap is mounted on or removed from the housing, and the processor 170 may detect the mounting or removal of the cap based on the signal corresponding to the mounting or removal.

According to an embodiment, the motion detection sensor may detect movement of the aerosol generating device 1. The motion detection sensor may be implemented using at least one of an acceleration sensor or a gyro sensor.

According to an embodiment, the sensor unit may further include, in addition to the sensors described above, at least one of a humidity sensor, an atmospheric pressure sensor, a magnetic sensor, a position sensor (global positioning system (GPS)), or a proximity sensor. The functions of the sensors would be instinctively understood by one of ordinary skill in the art in view of their names and thus detailed descriptions thereof are omitted herein.

According to an embodiment, the output unit may output information about the status of the aerosol generating device 1. The output unit may include, but is not limited to, a display, a haptic unit, and/or an audio output unit. For example, information about the aerosol generating device 1 may include the charging/discharging status of the power supply 130 of the aerosol generating device 1, the operating status of the source unit 20 or the radiating unit 30, the insertion/removal status of the aerosol-generating article and/or cartridge, the mounting and/or removal status of the cap, or the status in which the use of the aerosol generating device 1 is limited (e.g., detection of an abnormal article). The display may visually provide information to the user about the status of the aerosol generating device 1. For example, the display may include a light-emitting diode (LED) light emitting element, a liquid crystal display (LCD) panel, an organic light-emitting diode (OLED) display panel, etc. The display, if the display includes a touchpad, may also be used as an input device. The haptic unit may provide tactile information to the user about the status of the aerosol generating device 1. For example, the haptic component may include a vibration motor, a piezoelectric element, an electrical stimulation device, and the like. The audio output unit may provide information about the aerosol generating device 1 to the user audibly. For example, the audio output unit may convert an electrical signal into an audio signal and output the same externally.

According to an embodiment, the input unit may receive information input from a user. For example, the input unit may include a touch panel, a button, a key pad, a dome switch, a jog wheel, a jog switch, and the like.

According to an embodiment, the memory may be hardware that stores various data processed within the aerosol generating device 1, and may store data processed by the processor 170 and data to be processed. For example, the memory may include at least one type of storage medium among a flash memory type, a hard disk type, a multimedia card micro type, a card type memory (e.g., an SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. For example, the memory may store data about the operation time of the aerosol generating device 1, the maximum number of puffs, the current number of puffs, at least one temperature profile, and the user's smoking pattern.

According to an embodiment, the communication unit may include at least one component for communicating with another electronic device (e.g., a portable electronic device). For example, the communication unit may include a Bluetooth communication unit, a Bluetooth Low Energy (BLE) communication unit, a near field Communication unit, a wireless local area network (WLAN) communication unit, a Zigbee communication unit, an infrared (Infrared Data Association (IrDA)) communication unit, a wireless fidelity direct (WFD) communication unit, a ultra-wideband (UWB) communication unit, an Adaptive Network Topology (ANT)+ communication unit, a cellular network communication unit, an Internet communication unit, a computer network (e.g., LAN or WAN) communication unit, etc.

According to an embodiment, the processor 170 may control the temperature of the insertion space or the aerosol-generating article by controlling an amplification factor of the source unit 20 (e.g., the power amplifier 230). The processor 170 may control the amplification factor of the source unit 20 (e.g., the power amplifier 230) based on the temperature of the insertion space or the aerosol-generating article detected using the temperature sensor. The processor 170 may control the amplification factor of the source unit 20 (e.g., the power amplifier 230) based on the temperature profile and/or power profile stored in the memory.

Additionally, the processor 170 may control the temperature of the cartridge heater by controlling the supply of power from the power supply 130 to the cartridge heater. The processor 170 may control the temperature of the cartridge heater and/or power supplied to the cartridge heater, based on the temperature of the cartridge heater detected using the temperature sensor. The processor 170 may control the temperature of the cartridge heater and/or the power supplied to the cartridge heater based on the temperature profile and/or power profile stored in the memory.

In an embodiment, the processor 170 may prevent the insertion space, the aerosol-generating article, and/or the cartridge heater from overheating. For example, the processor 170 may control the operation of the power conversion circuit to reduce the amount of power supplied to the source unit 20 or the cartridge heater, or to stop supplying power to the source unit 20 or the cartridge heater, based on a determination that temperature of the insertion space, the aerosol-generating article, and/or the cartridge heater exceeds a preset threshold temperature.

According to an embodiment, the processor 170 may control power supply to the source unit 20 or the cartridge heater, based on a result detected by the sensor unit.

In an embodiment, the processor 170 may control power supply to the source unit 20 or the cartridge heater based on insertion and/or removal of the aerosol-generating article into the insertion space. For example, the processor 170 may control power to be supplied to the source unit 20 or the cartridge heater when it is determined that the aerosol-generating article has been inserted into the insertion space using the insertion detection sensor. The processor 170 may cut off the power supply to the source unit 20 or the cartridge heater if it is determined that the aerosol-generating article has been removed from the insertion space using the insertion detection sensor. The processor 170 may determine that the aerosol-generating article has been removed from the insertion space, if the temperature of the insertion space or the aerosol-generating article is above a limited temperature or if the temperature change gradient of the insertion space or the aerosol-generating article is equal to or above a set gradient.

In an embodiment, the processor 170 may control the power supply time and/or power supply amount of power supplied to the source unit 20 or the cartridge heater, based on the state of the aerosol-generating article. For example, the processor 170 may increase the power supply time (e.g., preheating time) of power supply to the source unit 20 or the cartridge heater, if it is determined that the aerosol-generating article is in an overly moist state by using the overly moist detection sensor.

In an embodiment, the processor 170 may control power supply to the source unit 20 or the cartridge heater based on whether the aerosol-generating article is to be reused. For example, the processor 170 may cut off power supply to the source unit 20 or the cartridge heater if it is determined that the aerosol-generating article has been used.

In an embodiment, the processor 170 may control power supply to the source unit 20 or the cartridge heater, based on whether the cartridge is engaged and/or removed. For example, the processor 170 may stop supplying power to the source unit 20 or the cartridge heater or control power not to be supplied to the source unit 20 or the cartridge heater if it is determined, by using the cartridge detection sensor, that the cartridge is removed.

In an embodiment, the processor 170 may control power supply to the source unit 20 or the cartridge heater based on whether the aerosol-generating material in the cartridge has been exhausted. For example, the processor 170 may determine that the aerosol-generating material in the cartridge is exhausted if it is determined that the temperature of the cartridge heater exceeds a limit temperature while preheating the cartridge heater (i.e., during the preheating period). If it is determined that the aerosol-generating material in the cartridge has been exhausted, the processor 170 may cut off the supply of power to the source unit 20 or the cartridge heater.

In an embodiment, the processor 170 may control power supply to the source unit 20 or the cartridge heater based on the availability of the cartridge. For example, the processor 170 may determine that the cartridge is no longer usable if it is determined that the current number of puffs is equal to or greater than the maximum number of puffs set for the cartridge based on data stored in the memory. Alternatively, the processor 170 may determine that the cartridge is unusable if the total time that the cartridge heater has been heated is equal to or greater than a preset maximum time or the total amount of power supplied to the cartridge heater is equal to or greater than a preset maximum amount of power. In this case, the processor 170 may stop supplying power to the source unit 20 or the cartridge heater or control power not to be supplied to the source unit 20 or the cartridge heater.

In an embodiment, the processor 170 may control power supply to the source unit 20 or the cartridge heater based on the user's puff. For example, the processor 170 may use a puff sensor to determine whether a puff has occurred and/or the intensity of the puff. The processor 170 may cut off the power supply to the source unit 20 or the cartridge heater if the number of puffs reaches a preset maximum number of puffs and/or if no puffs are detected for a preset period of time. The processor 170 may also control the supply of power to the source unit 20 or the cartridge heater when a puff is detected.

In an embodiment, the processor 170 may control power supply to the source unit 20 or the cartridge heater based on the authenticity and/or type of the aerosol-generating article (or the cartridge). For example, the processor 170 may use the cigarette identification sensor to detect the authenticity and/or type of the aerosol-generating article (or the cartridge). For example, the processor 170 may cut off power supply to the source unit 20 or the cartridge heater if the aerosol-generating article (or the cartridge) is detected to be counterfeit. The processor 170 may control (e.g., initiate) the supply of power to the source unit 20 or the cartridge heater when the aerosol-generating article (or the cartridge) is detected to be authentic. In another example, the processor 170 may control power supply to the source unit 20 or the cartridge heater differently depending on the type of the aerosol-generating article (or the cartridge). The processor 170 may control the amplification factor of the source unit 20 or the temperature and/or power of the cartridge heater, based on a first temperature profile (or a first power profile) when the aerosol-generating article (or the cartridge) is detected to be a first aerosol-generating article (or a first cartridge), and may control the amplification factor of the source unit 20 or the temperature and/or power of the cartridge heater, based on a second temperature profile (or a second power profile) when the aerosol-generating article (or the cartridge) is detected to be a second aerosol-generating article (or a second cartridge).

According to an embodiment, the processor 170 may control the output unit based on a result detected by the sensor unit. For example, the processor 170 may control the output unit to provide visual, tactile and/or auditory information indicating that the aerosol generating device 1 is about to be terminated, when the number of puffs counted using the puff sensor reaches a preset number. For example, the processor 170 may control the output unit to provide visual, tactile and/or auditory information about the temperature of the insertion space, the aerosol-generating article, or the cartridge heater.

According to an embodiment, the processor 170 may store and update a history of events that occurred in the memory based on the occurrence of a given event. For example, the event may include operations such as detection of insertion of an aerosol-generating article, initiation of heating of an aerosol-generating article, detection of a puff, termination of a puff, detection of overheating, detection of overvoltage application to a cartridge heater, termination of heating of an aerosol-generating article, turning on/off power of the aerosol generating device 1, initiation of charging of the power supply 130, detection of overcharge of the power supply 130, termination of charging of the power supply 130, etc., performed in the aerosol generating device 1. For example, the history of events may include the time an event occurred, log data corresponding to the event, etc. For example, if a given event is detection of insertion of an aerosol-generating article, log data corresponding to the event may include data about sensing values of an insertion detection sensor, etc. For example, if a given event is overheating detection of a cartridge heater, log data corresponding to the event may include data about a temperature of the cartridge heater, a voltage applied to the cartridge heater, a current flowing through the cartridge heater, etc.

According to an embodiment, the processor 170 may control the communication unit to form a communication link with an external device, such as a user's mobile terminal.

According to an embodiment, the processor 170 may release a restriction on the use of at least one function (e.g., a heating function) of the aerosol generating device 1 when data regarding authentication is received from an external device via a communications link. For example, data regarding authentication may include the user's date of birth, a unique number that identifies the user, whether the user has completed authentication, etc.

According to an embodiment, the processor 170 may transmit data about the status of the aerosol generating device 1 to an external device via a communication link (e.g., remaining capacity of the power supply 130, operating mode, etc.). The transmitted data may be output through a display of an external device, etc.

According to an embodiment, when a request for location search of the aerosol generating device 1 is received from an external device via a communication link, the processor 170 may control the output unit to perform an operation corresponding to the location search. For example, the processor 170 may control the haptic unit to generate vibration or control the display to output an object corresponding to the location search and search termination.

According to an embodiment, the processor 170 may perform a firmware update when firmware data is received from an external device via a communication link.

According to an embodiment, the processor 170 may transmit data on sensed values of at least one sensor unit to an external server (not shown) via a communication link, and receive and store a learning model generated by learning the sensed values through machine learning, such as deep learning, from the server. The processor 170 may perform operations such as determining a user's inhalation pattern and generating a temperature profile using a learning model received from a server.

Although not illustrated in FIG. 1, the aerosol generating device 1 may further include a power protection circuit. The power protection circuit may include at least one switching element and may cut off the current path to the power supply 130 in response to overcharge and/or overdischarge of the power supply 130.

An aerosol-generating article as described herein may include at least one aerosol-generating rod (e.g., a medium portion) and at least one filter rod. The radiating unit 30 may be arranged to correspond to at least one aerosol-generating rod, and may be designed differently depending on the arrangement order and/or position of the aerosol-generating rod and the filter rod. The aerosol-generating rod may include at least one of nicotine, an aerosol-generating material, and an additive. For example, the aerosol-generating material may include glycerin (e.g., vegetable glycerin (VG)) and/or propylene glycol (PG), and may also include various other materials. For example, the additive may include flavoring agents and/or organic acids, and may also include various other substances. For example, the aerosol-generating rod may include an aerosol-generating substrate (e.g., a sheet) impregnated with a liquid non-tobacco material (e.g., an aerosol-generating material and/or nicotine), and/or may include a solid tobacco material (e.g., leaf tobacco, reconstituted tobacco, etc.). The tobacco material may be included in the aerosol-generating rod in various forms, such as cut tobacco, granules, or powder. In an embodiment, the additive of the aerosol-generating rod may include a basic substance. Based on the basic material, the nicotine of the tobacco material included in the aerosol-generating rod may have an alkaline pH (e.g., pH 7.0 or higher). In this case, freebase nicotine may be released from the aerosol-generating rod even at low temperatures. According to an embodiment, the aerosol-generating rod may include two or more aerosol-generating rods, wherein the two or more aerosol-generating rods may each include tobacco material and/or non-tobacco material. Although not shown, at least one aerosol-generating rod and at least one filter rod may be individually and/or integrally wrapped by at least one wrapper. In the disclosure, the aerosol-generating article may be referred to as a stick.

The cartridge referred to in the disclosure may include an aerosol-generating material having any one of a liquid state, a solid state, a gaseous state, or a gel state therein. The aerosol-generating material may include a liquid composition. For example, the liquid composition may be a liquid including a tobacco-containing material including a volatile tobacco flavor component, or may be a liquid including a non-tobacco material. The cartridge may include a storage portion containing an aerosol-generating material and/or a liquid transfer means impregnated with (containing) the aerosol-generating material. For example, the liquid transfer medium may include a wick such as cotton fibers, ceramic fibers, glass fibers, porous ceramics, etc. The cartridge heater may be included in the cartridge in the form of a coil surrounding (or winding) the liquid transfer means or in a structure contacting one side of the liquid transfer means. Alternatively, the cartridge heater may be included in the aerosol generating device 1 that is separable from the cartridge.

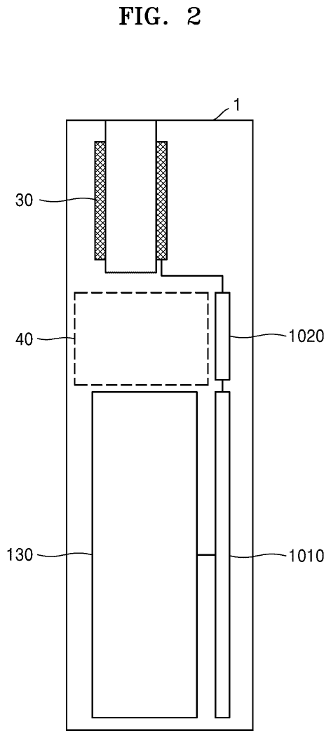

FIG. 2 is a schematic cross-sectional view of an aerosol generating device according to an embodiment.

Referring to FIG. 2, the aerosol generating device 1 may further include, in addition to the components described with reference to FIG. 1 (e.g., the power supply 130, the radiating unit 30, etc.), a first circuit board 1010, a second circuit board 1020, and a heat dissipation unit 40. However, it will be understood by those skilled in the art related to the present embodiment that some of the components illustrated in FIG. 2 may be omitted or new components may be added according to the design of the aerosol generating device 1.

The first circuit board 1010 may refer to a printed circuit board (PCB) on which circuit elements for controlling the overall operation of the aerosol generating device 1 are mounted. For example, the first circuit board 1010 may include at least one of the components of the control unit 10 described with reference to FIG. 1 (e.g., the processor 170, etc.). Since the circuit elements mounted on the first circuit board 1010 do not process high-frequency signals (e.g., signals having a frequency of 3 MHz or higher), it may be desirable for the first circuit board 1010 to be a PCB that is inexpensive and easy to process, even if it has limitations in high-frequency characteristics. In an example, the first circuit board 1010 may be, but is not limited to, a Flame Retardant 4 (FR4) PCB.

The second circuit board 1020 may refer to a PCB on which circuit elements for generating and/or amplifying RF signals are mounted. For example, the second circuit board 1020 may include at least one of the components of the source unit 20 described with reference to FIG. 1 (e.g., the RF signal generation circuit 210, the drive amplifier 220, the power amplifier 230, etc.). Since the circuit elements mounted on the second circuit board 1020 process high-frequency signals (e.g., RF signals), it may be desirable for a PCB to be manufactured from materials optimized for high-frequency and high-speed signal transmission. For example, the second circuit board 1020 may be manufactured from a low dielectric material to minimize signal loss at high frequencies. Additionally, since a large amount of heat may be generated during the process of amplifying an RF signal, it may be desirable for the second circuit board 1020 to have better temperature stability than the first circuit board 1010. In an example, the second circuit board 1020 may be, but is not limited to, a Rogers PCB.

The second circuit board 1020 may be arranged spaced apart from the first circuit board 1010. Since the second circuit board 1020 is to transmit the generated and/or amplified RF signal to the radiating unit 30, the second circuit board 1020 may be arranged closer to the radiating unit 30 than the first circuit board 1010. For example, when FIG. 2 is a cross-sectional view of the aerosol generating device 1 viewed from the front, the second circuit board 1020 may be arranged on an upper side of the first circuit board 1010 and spaced apart from the first circuit board 1010 along the same axis. The second circuit board 1020 may be physically separated from the first circuit board 1010, but may be electrically connected thereto. The second circuit board 1020 may be electrically connected to the first circuit board 1010 through a connecting means such as a connector, a flexible PCB, a wire, a cable, etc.

As described above, the aerosol generating device 1 according to the disclosure may include the first circuit board 1010 on which circuit elements for controlling the overall operation of the aerosol generating device 1 are mounted, and the second circuit board 1020 on which circuit elements for generating and/or amplifying an RF signal are mounted. In other words, the aerosol generating device 1 may appropriately distribute circuit elements corresponding to respective functions to a circuit board more suitable for implementing each function by distinguishing the circuit elements by function and mounting the same on different circuit boards. Accordingly, circuit elements for implementing dielectric heating may operate more stably.

Meanwhile, if the power supply 130 is charged and/or discharged above a certain threshold temperature, normal operation may not occur or the lifespan may be reduced. Therefore, it may be desirable to prevent heat generated from the second circuit board 1020 during the process of generating and/or amplifying an RF signal from being transferred to the power supply 130 as much as possible. To this end, the second circuit board 1020 may be arranged so as not to overlap the power supply 130 in any of the left-right, front-back, and up-down directions. Accordingly, a distance between a point where heat is generated on the second circuit board 1020 and the power supply 130 increases, and the area where heat transfer occurs decreases, and thus, the heat transferred to the power supply 130 may be minimized.

Additionally, the aerosol generating device 1 may include the heat dissipation unit 40 to effectively release or disperse heat generated from the second circuit board 1020 so as to minimize transfer of heat generated from the second circuit board 1020, to the power supply 130. The heat dissipation unit 40 may be arranged in contact with or adjacent to at least one surface of the second circuit board 1020. As illustrated in FIG. 2, the heat dissipation unit 40 may be positioned adjacent to a rear surface (i.e., the left side in the cross-sectional view of FIG. 2) of the second circuit board 1020. The circuit elements for generating and/or amplifying RF signals may be arranged on a front surface (i.e., the right side in the cross-sectional view of FIG. 2) of the second circuit board 1020. Accordingly, heat generated from the circuit elements (e.g., the drive amplifier 220 and/or the power amplifier 230 of FIG. 1) may be transferred to the power supply 130 through the second circuit board 1020, thereby reducing heat transfer. However, since FIG. 2 is only an example, the heat dissipation unit 40 may be arranged on a front surface of the second circuit board 1020 or may be arranged on both the front surface and the rear surface thereof. Additionally, the heat dissipation unit 40 may be in contact with or coupled to at least one surface of the second circuit board 1020.

The heat dissipation unit 40 may include at least one of a heat sink, a fan, and a heat pipe. The heat sink may include a highly thermally conductive material to absorb heat and have a relatively large surface area to effectively dissipate the heat into the atmosphere. In an example, the heat sink may include, but is not limited to, a sheet of graphite. The heat sink may include a metal material such as copper or aluminum, or may include fin or wing structures to increase surface area. The fan may move heat quickly through air circulation and promote heat exchange with the atmosphere. The heat pipe may have a structure in which a refrigerant is included within an outer material including at least one of a metal material, a ceramic material, and a carbon material. When heat is applied to one end of the heat pipe, the refrigerant inside the heat pipe evaporates, allowing heat energy to move to the other end of the heat pipe. The heat pipe may dissipate heat efficiently. Due to the heat dissipation unit 40, stable operation of the power supply 130 may be ensured, and the lifespan of the power supply 130 may be increased.

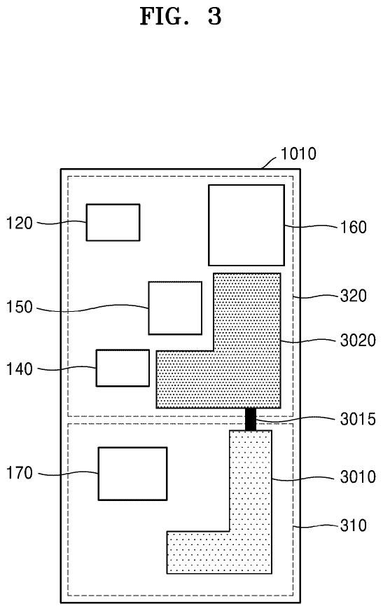

While only the first circuit board 1010 and the second circuit board 1020 are illustrated in FIG. 2, the aerosol generating device 1 may further include other circuit boards. For example, the aerosol generating device 1 may further include modular and/or functional PCBs, such as a sensor PCB, a button PCB (e.g., an RGB-KEY PCB), etc. The number of modular and/or functional PCBs included in the aerosol generating device 1 may be determined as an appropriate number depending on the application. The first circuit board 1010 and the second circuit board 1020 will be described in detail with reference to FIGS. 3 to 7 below.

FIG. 3 is a diagram illustrating one surface of a first circuit board according to an embodiment.

Referring to FIG. 3, an example is illustrated in which the charging circuit 120, the first power converter 140, the second power converter 150, the third power converter 160, and the processor 170 described with reference to FIG. 1 are arranged on the first circuit board 1010. FIG. 3 is an example for describing an arrangement method of circuit elements mounted on the first circuit board 1010, and thus, it will be understood by those skilled in the art related to the present embodiment that other examples that do not contradict the arrangement method may also be included in various embodiments. Additionally, although not illustrated in FIG. 3, the power connector 110 described with reference to FIG. 1 may also be arranged on the first circuit board 1010.

A digital area 310 in which a digital circuit including the processor 170 is mounted and an analog area 320 in which an analog circuit including at least one power conversion circuit (e.g., the first power converter 140, the second power converter 150, and the third power converter 160) is mounted may be electrically and physically separated from each other within the first circuit board 1010.

For example, as illustrated in FIG. 3, when the digital area 310 is arranged on the lower side of the first circuit board 1010, the analog area 320 may be arranged in the remaining area other than the digital area 310, and thus the digital area 310 and the analog area 320 may be physically separated. Additionally, the digital area 310 and the analog area 320 may respectively include a ground. For example, the first circuit board 1010 may each include a digital ground 3010 connected to a digital circuit, and an analog ground 3020 connected to an analog circuit. Accordingly, the digital area 310 and the analog area 320 may be electrically separated from each other.

Analog circuits, including at least one power conversion circuit, process continuous signals and may utilize relatively large voltages and/or currents. A digital circuit including the processor 170 may process discrete signals and utilize relatively small voltages and/or currents. As described above, as analog circuits and digital circuits process signals with different characteristics, connecting these to a common ground may cause performance degradation and signal interference due to noise. Therefore, it may be desirable to separate the digital ground 3010 and the analog ground 3020 from each other to prevent the occurrence of noise and signal interference.

The digital ground 3010 and the analog ground 3020 may be separated from each other, but be electrically connected only at a single point by a noise reduction element 3015. Accordingly, the digital ground 3010 and the analog ground 3020 may provide a common reference potential while minimizing the occurrence of noise and signal interference. The noise reduction element 3015 may include at least one of a zero-ohm resistor and a bead. The bead may be a type of inductor that may block electromagnetic waves or remove or absorb high-frequency noise.

The charging circuit 120 may be a hybrid circuit that operates in a form in which analog circuits and digital circuits are combined, but since the charging circuit 120 performs the function of controlling voltage and/or current, the charging circuit 120 may be arranged in the analog area 320. Each of the first power converter 140, the second power converter 150, and the third power converter 160 may be arranged in a manner that does not include opposite facing sides to minimize influences on each other (e.g., transfer of heat, noise, etc.). For example, as illustrated in FIG. 3, the first power converter 140, the second power converter 150, and the third power converter 160 may be arranged so as not to overlap each other along a diagonal line passing through a center of the analog area 320, but are not limited thereto.

FIG. 3 may be a diagram illustrating a front surface of the first circuit board 1010 (i.e., a surface in the right direction in the cross-sectional view of FIG. 2). Since a certain amount of heat may be generated during a process of converting power, by a power conversion circuit, the power conversion circuit may be arranged on a surface of the first circuit board 1010, which does not face the heat-sensitive power supply 130. However, the disclosure is not limited thereto.

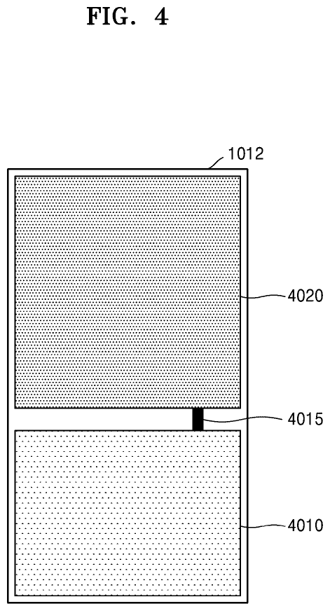

The first circuit board 1010 may be a double-sided circuit board or a multilayer circuit board. When the first circuit board 1010 is a multilayer circuit board, the first circuit board 1010 may include one or more inner layers (e.g., a ground layer) in addition to both sides. If the first circuit board 1010 is a multilayer circuit board including at least one ground layer therein, the digital ground 3010 and the analog ground 3020 may also be formed in at least one ground layer. Referring to FIG. 4 below, a case in which the first circuit board 1010 is a multilayer circuit board is described.

FIG. 4 is a diagram illustrating a ground layer of a first circuit board according to an embodiment.

Referring to FIG. 4, a ground layer 1012 inside the first circuit board 1010 is illustrated. The digital ground 4010 and the analog ground 4020 may each be arranged in physically separated areas within the ground layer 1012. For example, the digital ground 4010 may be arranged at a position corresponding to a digital area (e.g., the digital area 310 of FIG. 3) in which a digital circuit including the processor 170 is mounted on the front surface of the first circuit board 1010. Additionally, the analog ground 4020 may be arranged at a position corresponding to an analog area (e.g., the analog area 320 of FIG. 3) in which an analog circuit including at least one power conversion circuit (e.g., the first power converter 140, the second power converter 150, and the third power converter 160) is mounted on the front surface of the first circuit board 1010.

A digital circuit mounted on the front surface of the first circuit board 1010 may be connected to the digital ground 4010 through a connecting means such as a via. Additionally, an analog circuit mounted on the front surface of the first circuit board 1010 may be connected to the analog ground 4020 through a connecting means such as a via. Accordingly, digital circuits and analog circuits may be electrically separated from each other. Since the larger the area of the ground, the better, the shapes of the digital ground 4010 and the analog ground 4020 are illustrated in a simplified manner in FIG. 4, but if an element sensitive to heat or noise generated from the ground is arranged on at least one of both sides of the first circuit board 1010, the ground may not be formed at a location corresponding to (e.g., overlapping) the area where the element is arranged. Additionally, the area of the analog ground 4020 may be wider than the area of the digital ground 4010.

The digital ground 4010 and the analog ground 4020 may be electrically connected to each other at only a single point by a noise reduction element 4015 to provide a common reference potential while minimizing the occurrence of noise and signal interference. The noise reduction element 4015 may include at least one of a zero-ohm resistor and a bead. The bead may be a type of inductor that may block electromagnetic waves or remove or absorb high-frequency noise.

An example in which a ground is formed on the front surface of the first circuit board 1010 is described above with reference to FIG. 3, and an example in which a ground is formed on the ground layer 1012 is described with reference to FIG. 4. However, the ground may be formed on a plurality of surfaces and/or layers among both surfaces of the first circuit board 1010 and at least one ground layer. In this case, digital grounds (e.g., the digital ground 3010 and the digital ground 4010) formed on different layers or surfaces may be connected to each other, and analog grounds (e.g., the analog ground 3020 and the analog ground 4020) formed on different layers or surfaces may also be connected to each other. However, it may be desirable for the connection between the digital grounds and connection the analog grounds to be formed by a noise reduction element (e.g., the noise reduction element 3015 of FIG. 3 or the noise reduction element 4015 of FIG. 4) only on one of the multiple surfaces and/or layers.

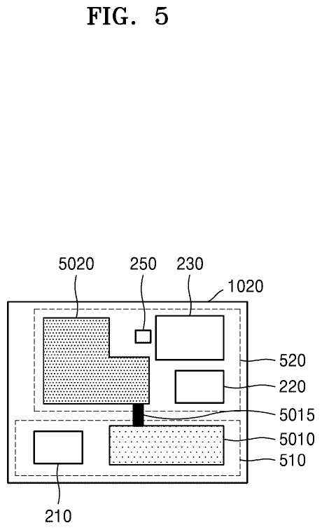

FIG. 5 is a diagram illustrating one surface of a second circuit board according to an embodiment.

Referring to FIG. 5, an example is illustrated, in which the RF signal generation circuit 210, the drive amplifier 220, the power amplifier 230, and the temperature sensing circuit 250 described with reference to FIG. 1 are arranged on the second circuit board 1020. FIG. 5 may be a diagram illustrating the front surface of the second circuit board 1020 (i.e., a surface in the right direction in the cross-sectional view of FIG. 2). Since FIG. 5 is an example for describing an arrangement method of circuit elements mounted on the second circuit board 1020, it will be understood by those skilled in the art related to the present embodiment that other examples that do not contradict the arrangement method may also be included in various embodiments.

A first region 510 in which the RF signal generation circuit 210 is mounted and a second region 520 in which at least one amplifier (e.g., the drive amplifier 220 and/or the power amplifier 230) is mounted within the second circuit board 1020 may be physically separated. For example, as illustrated in FIG. 5, when the first region 510 is arranged on a lower side of the second circuit board 1020, the second region 520 may be arranged in the remaining region other than the first region 510, so that the first region 510 and the second region 520 may be physically separated from each other. Since a large amount of heat may be generated from at least one amplifier during the process of amplifying an RF signal, it may be desirable for the RF signal generation circuit 210 and at least one amplifier to be positioned as far apart as possible in order to ensure stable operation of the RF signal generation circuit 210.

The RF signal generation circuit 210 and at least one amplifier may be positioned close to two edges or corners of the second circuit board 1020 that are opposite to each other with respect to a center of the second circuit board 1020. For example, as illustrated in FIG. 5, the RF signal generation circuit 210 may be positioned closer to a lower left corner of the second circuit board 1020, while the power amplifier 230 may be positioned closer to an upper right corner of the second circuit board 1020. Here, a circuit element positioned close to an edge or corner may indicate, but is not limited to, that a distance between the circuit element and the edge or corner is shorter than a distance between the circuit element and the center of the second circuit board 1020.

The second circuit board 1020 may include a first ground 5010 connected to the RF signal generation circuit 210, and a second ground 5020 disposed separately from the first ground 5010 and connected to at least one amplifier. Although both the RF signal generation circuit 210 and at least one amplifier correspond to analog circuits, considering that the at least one amplifier uses much greater power (e.g., voltage and/or current) than the RF signal generation circuit 210, it may be desirable for the first ground 5010 to which the RF signal generation circuit 210 is connected and the second ground 5020 to which the at least one amplifier is connected to be separated in order to ensure stable operation of the RF signal generation circuit 210. The first ground 5010 and the second ground 5020 may be electrically connected at a single point by a noise reduction element 5015. The noise reduction element 5015 may include at least one of a zero-ohm resistor and a bead. The bead may be a type of inductor that may block electromagnetic waves or remove or absorb high-frequency noise.

The temperature sensing circuit 250 may be arranged adjacent to the power amplifier 230. The temperature sensing circuit 250 may be used to prevent overheating of the second circuit board 1020. The most heat may be generated from the power amplifier 230 on the second circuit board 1020. Thus, the temperature sensing circuit 250 may be arranged as close as possible to the power amplifier 230 to sensitively measure a temperature change of the second circuit board 1020. A processor (e.g., the processor 170 of FIG. 1 or FIG. 3) may, in response to determining that a temperature measured by the temperature sensing circuit 250 exceeds a preset threshold, stop operation of at least one of the RF signal generation circuit 210 and the at least one amplifier. Accordingly, overheating of the second circuit board 1020 may be prevented.

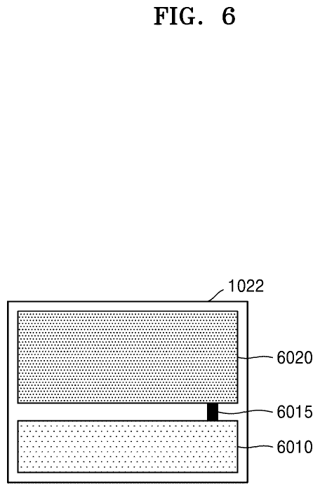

The second circuit board 1020 may be a double-sided circuit board or a multilayer circuit board. If the second circuit board 1020 is a multilayer circuit board, the second circuit board 1020 may include one or more inner layers (e.g., a ground layer) in addition to both sides. If the second circuit board 1020 is a multilayer circuit board including at least one ground layer therein, the first ground 5010 and the second ground 5020 may also be formed in at least one ground layer. Referring to FIG. 6 below, a case in which the second circuit board 1020 is a multilayer circuit board will be described.

FIG. 6 is a diagram illustrating a ground layer of a second circuit board according to an embodiment.

Referring to FIG. 6, a ground layer 1022 inside the second circuit board 1020 is illustrated. The first ground 6010 and the second ground 6020 may each be arranged in physically separated areas within the ground layer 1022. For example, the first ground 6010 may be arranged at a position corresponding to the first region 510 where the RF signal generation circuit 210 is mounted on the front surface of the second circuit board 1020. Additionally, the second ground 6020 may be arranged at a position corresponding to the second region 520 on the front surface of the second circuit board 1020 where at least one amplifier (e.g., the drive amplifier 220 and/or the power amplifier 230) is mounted.

The RF signal generation circuit 210 mounted on the front surface of the second circuit board 1020 may be connected to the first ground 6010 through a connecting means such as a via. Additionally, at least one amplifier mounted on the front surface of the second circuit board 1020 may be connected to the second ground 6020 through a connecting means such as a via. Accordingly, the first ground 6010 to which the RF signal generation circuit 210 is connected and the second ground 6020 connected to at least one amplifier may be separated. Since the larger the area of the ground, the better, the shapes of the first ground 6010 and the second ground 6020 are illustrated in a simplified manner in FIG. 6, but if an element sensitive to heat or noise generated from the ground is arranged on at least one of both sides of the second circuit board 1020, the ground may not be formed at a location corresponding to (e.g., overlapping) the area where the element is arranged. Additionally, the area of the second ground 6020 may be larger than the area of the first ground 6010.

The first ground 6010 and the second ground 6020 may be electrically connected to each other at only a single point by a noise reduction element 6015 to provide a common reference potential while minimizing the occurrence of noise and signal interference. The noise reduction element 6015 may include at least one of a zero-ohm resistor and a bead. The bead may be a type of inductor that may block electromagnetic waves or remove or absorb high-frequency noise.

An example in which a ground is formed on the front surface of the second circuit board 1020 is described above with reference to FIG. 5, and an example in which a ground is formed on the ground layer 1022 is described above with reference to FIG. 6. However, the ground may be formed on a plurality of surfaces and/or layers among both surfaces of the second circuit board 1020 and at least one ground layer. In this case, first grounds (e.g., the first ground 5010 and the first ground 6010) formed in different layers or surfaces may be connected to each other, and second grounds (e.g., the second ground 5020 and the second ground 6020) formed in different layers or surfaces may be connected to each other. However, the connection between the first grounds and the second grounds may be formed by a noise reduction element (e.g., the noise reduction element 5015 or the noise reduction element 6015) only in one of the plurality of surfaces and/or layers.

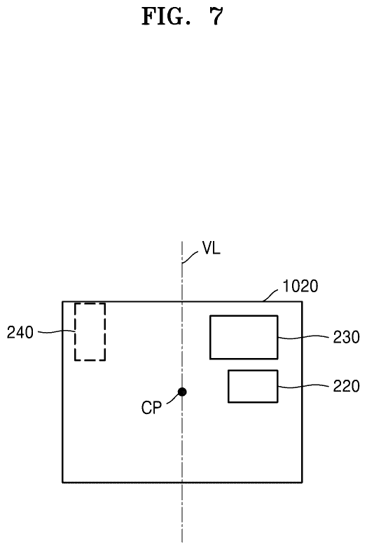

FIG. 7 is a diagram for describing an arrangement of a directional coupler according to an embodiment.

Referring to FIG. 7, the second circuit board 1020 may further include the directional coupler 240 that separately receives an amplified RF signal and reflected electromagnetic waves reflected from the insertion space after being radiated by a radiating unit (e.g., the radiating unit 30 of FIG. 1 or FIG. 2). In order for the directional coupler 240 to accurately detect reflected electromagnetic waves corresponding to relatively a small signal, the directional coupler 240 may be arranged as far away as possible from at least one amplifier (e.g., the drive amplifier 220 and/or the power amplifier 230) that outputs relatively large signals.

The directional coupler 240 and at least one amplifier may be respectively arranged in areas separated by a vertical line VL passing through a center CP of the second circuit board 1020. For example, as illustrated in FIG. 7, when the directional coupler 240 is arranged in a left region, the drive amplifier 220 and/or the power amplifier 230 may be arranged in a right region. However, it is not limited thereto, and the directional coupler 240 and at least one amplifier may be respectively arranged in areas separated by a horizontal line (not shown) passing through the center CP of the second circuit board 1020.

Additionally, the directional coupler 240 and at least one amplifier may be positioned close to two edges or corners that are opposite to each other with respect to the center CP of the second circuit board 1020 among the edges or corners of the second circuit board 1020. For example, as illustrated in FIG. 7, the directional coupler 240 may be positioned close to a left edge of the second circuit board 1020, while the drive amplifier 220 and/or the power amplifier 230 may be positioned close to a right edge of the second circuit board 1020. Here, a circuit element positioned close to an edge or corner may indicate, but is not limited to, that a distance between the circuit element and the edge or corner is shorter than a distance between the circuit element and the center of the second circuit board 1020.

In an embodiment, the directional coupler 240 and at least one amplifier may be positioned on different surfaces of the second circuit board 1020. For example, if at least one amplifier is arranged on the front surface of the second circuit board 1020, the directional coupler 240 may be arranged on the rear surface of the second circuit board 1020. In this case, the directional coupler 240 and at least one amplifier may be arranged so as not to overlap each other when viewed from the front or rear surface of the second circuit board 1020. Even in the example in which the directional coupler 240 and at least one amplifier are positioned on different surfaces of the second circuit board 1020, the directional coupler 240 may be positioned as far apart as possible from the at least one amplifier.

As described with reference to FIGS. 3 to 7, according to the aerosol generating device 1 of the disclosure, circuit elements mounted within a same circuit board may be arranged in an appropriate manner in consideration of each operating condition and/or operating characteristic. Accordingly, stable operation of circuit elements implementing dielectric heating may be ensured.

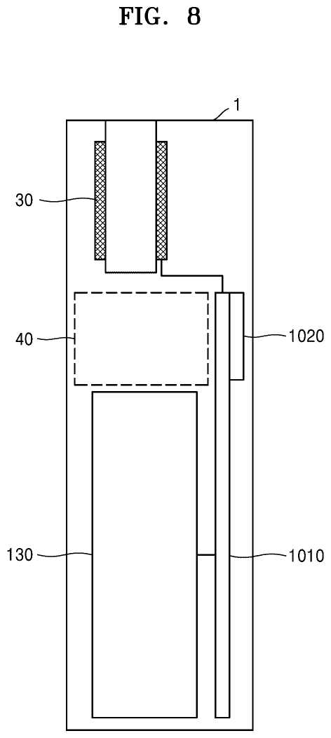

FIG. 8 is a schematic cross-sectional view of an aerosol generating device according to another embodiment.

Referring to FIG. 8, the aerosol generating device 1 may further include the first circuit board 1010, the second circuit board 1020, and the heat dissipation unit 40 in addition to the components described with reference to FIG. 1 (e.g., the power supply 130, the radiating unit 30, etc.). However, it will be understood by those skilled in the art related to the present embodiment that some of the components illustrated in FIG. 8 may be omitted or new components may be added depending on the design of the aerosol generating device 1.

The first circuit board 1010 may refer to a printed circuit board (PCB) on which circuit elements for controlling the overall operation of the aerosol generating device 1 are mounted. For example, the first circuit board 1010 may include at least one of the components of the control unit 10 described with reference to FIG. 1 (e.g., the processor 170, etc.). Since the first circuit board 1010 is to mount most of the circuit elements included in the aerosol generating device 1, the first circuit board 1010 may include a PCB that is inexpensive and easy to process. In an example, the first circuit board 1010 may be, but is not limited to, a Flame Retardant 4 (FR4) PCB.

Since the first circuit board 1010 has limited high-frequency performance in exchange for being relatively inexpensive, on the first circuit board 1010, circuit elements that do not process high-frequency signals (e.g., signals having a frequency of 3 MHz or higher) may be mounted. However, even if a circuit element processes a high-frequency signal, as long as the circuit element that is guaranteed to operate normally on the first circuit board 1010 or does not have a negative effect on other circuit elements, the circuit element may be mounted on the first circuit board 1010. For example, the RF signal generation circuit 210 described with reference to FIG. 1 generates a high-frequency signal but outputs only low power, and thus the RF signal generation circuit 210 may be mounted on the first circuit board 1010.

The second circuit board 1020 may refer to a PCB on which circuit elements for amplifying RF signals are mounted. For example, the second circuit board 1020 may include at least one amplifier (e.g., the drive amplifier 220, the power amplifier 230, etc.) among the components of the source unit 20 described with reference to FIG. 1. Since the circuit elements mounted on the second circuit board 1020 process high-frequency and/or high-power signals, the second circuit board 1020 may be a PCB to be manufactured from materials optimized for high-frequency and high-speed signal transmission. For example, the second circuit board 1020 may be manufactured from a low dielectric material to minimize signal loss at high frequencies. Additionally, since a large amount of heat may be generated during a process of amplifying an RF signal, the second circuit board 1020 may have better temperature stability than the first circuit board 1010. In an example, the second circuit board 1020 may be, but is not limited to, a Rogers PCB.

As described above, the aerosol generating device 1 according to the disclosure may ensure normal operation of each circuit element without significantly increasing manufacturing costs by distinguishing the circuit elements according to operating conditions and/or operating characteristics and mounting the circuit elements on different circuit boards.

The second circuit board 1020 may be directly mounted on a surface of the first circuit board 1010. As described above, according to the aerosol generating device 1 of the disclosure, mass production and low cost may be achieved through an automated assembly process along with miniaturization of the entire circuit board portion by directly mounting another circuit board on a surface of one circuit board using Surface Mount Technology (SMT).

Meanwhile, if the power supply 130 is charged and/or discharged at a certain threshold temperature or above, normal operation may not occur or the lifespan may be reduced. Therefore, it may be desirable to prevent heat generated from the second circuit board 1020 during the process of amplifying the RF signal from being transferred to the power supply 130 as much as possible. To this end, the second circuit board 1020 may be arranged so as not to overlap the power supply 130 in any of the left-right, front-back, and up-down directions.

In an example, the power supply 130 and the first circuit board 1010 may be arranged parallel to each other, and the first circuit board 1010 may include a portion extending beyond one end of the power supply 130. The second circuit board 1020 may be mounted on a surface of the extending portion. Additionally, the second circuit board 1020 may be mounted on one of the two surfaces of the first circuit board 1010, which does not face the power supply 130. Accordingly, as a distance between a point where heat is generated on the second circuit board 1020 and the power supply 130 increases, and the area where heat transfer occurs decreases, heat transferred from the power supply 130 may be minimized.

Additionally, the aerosol generating device 1 may include the heat dissipation unit 40 to effectively release or disperse heat generated from the second circuit board 1020 so as to minimize heat generated from the second circuit board 1020 from being transferred to the power supply 130. The heat dissipation unit 40 may be arranged in contact with or adjacent to at least one surface of the second circuit board 1020. As illustrated in FIG. 8, the heat dissipation unit 40 may be positioned adjacent to a portion of the rear surface of the first circuit board 1010, on which the second circuit board 1020 is mounted. Circuit elements for amplifying the RF signal may be arranged on the front surface of the second circuit board 1020 (i.e., a surface in the right direction in the cross-sectional view of FIG. 8). Accordingly, heat generated from circuit elements (e.g., the drive amplifier 220 and/or the power amplifier 230 of FIG. 1) may be transferred to the power supply 130 through the first circuit board 1010, the second circuit board 1020, and/or the heat dissipation unit 40, and thus heat transfer may be reduced. However, since FIG. 8 is only an example, the heat dissipation unit 40 may be arranged in contact with or adjacent to the front surface of the second circuit board 1020, or may be arranged adjacent to both the front surface and the rear surface of the second circuit board 1020.

The heat dissipation unit 40 may include at least one of a heat sink, a fan, and a heat pipe. The heat sink may include a highly thermally conductive material to absorb heat and have a relatively large surface area to effectively dissipate the heat into the atmosphere. In an example, the heat sink may be, but is not limited to, a sheet of graphite. The heat sink may include a metal material such as copper or aluminum, or may include fin or wing structures to increase surface area. The fan may move heat quickly through air circulation and promote heat exchange with the atmosphere. The heat pipe may have a structure in which a refrigerant is included within an outer material including at least one of a metal material, a ceramic material, and a carbon material. When heat is applied to one end of the heat pipe, the refrigerant inside the heat pipe evaporates, allowing heat energy to move to the other end of the heat pipe. The heat pipe may dissipate heat efficiently. Due to the heat dissipation unit 40, stable operation of the power supply 130 may be ensured, and the lifespan of the power supply 130 may be increased.

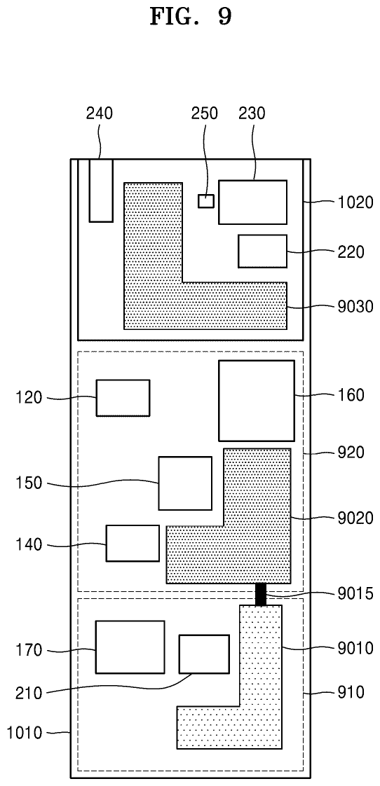

Although only the first circuit board 1010 and the second circuit board 1020 are illustrated in FIG. 8, the aerosol generating device 1 may further include other circuit boards. For example, the aerosol generating device 1 may further include modular and/or functional PCBs, such as a sensor PCB, a button PCB (e.g., an RGB-KEY PCB), etc. The number of modular and/or functional PCBs included in the aerosol generating device 1 may be determined as an appropriate number depending on the application. The first circuit board 1010 and the second circuit board 1020 are described in detail with reference to FIGS. 9 to 12 below.

FIG. 9 is a diagram illustrating one surface of each of a first circuit board and a second circuit board according to an embodiment.

Referring to FIG. 9, an example is illustrated, in which the charging circuit 120, the first power converter 140, the second power converter 150, the third power converter 160, the processor 170, and the RF signal generation circuit 210 described with reference to FIG. 1 are mounted on the first circuit board 1010, and the drive amplifier 220, the power amplifier 230, the directional coupler 240, and the temperature sensing circuit 250 described with reference to FIG. 1 are mounted on the second circuit board 1020. FIG. 9 is an example for describing an arrangement method of circuit elements mounted on the first circuit board 1010 and the second circuit board 1020, and thus, it will be understood by those skilled in the art related to the present embodiment that other examples that do not contradict the arrangement method may also be included in various embodiments. Additionally, although not illustrated in FIG. 9, the power connector 110 described with reference to FIG. 1 may also be arranged on the first circuit board 1010.

A first region 910 in which a digital circuit including the processor 170 is mounted within the first circuit board 1010 and a second region 920 in which an analog circuit including at least one power conversion circuit (e.g., the first power converter 140, the second power converter 150, and the third power converter 160) is mounted may be electrically and physically separated.

For example, as illustrated in FIG. 9, when the second circuit board 1020 is mounted in an upper portion of the first circuit board 1010 and the first region 910 is positioned in a lower portion of the first circuit board 1010, the second region 920 may be positioned in the remaining region excluding the region where the second circuit board 1020 is mounted and the first region 910, and thus the first region 910 and the second region 920 may be physically separated. Additionally, the first region 910 and the second region 920 may each include a ground. For example, the first circuit board 1010 may include a first ground 9010 connected to circuit elements disposed in the first region 910, and a second ground 9020 connected to circuit elements disposed in the second region 920. Accordingly, the circuit elements arranged in the first region 910 and the circuit elements arranged in the second region 920 may be electrically separated from each other.

Analog circuits, including at least one power conversion circuit, may process continuous signals and use relatively large voltages and/or currents. A digital circuit including the processor 170 may process discrete signals and use relatively small voltages and/or currents. As described above, as analog circuits and digital circuits process signals with different characteristics, connecting these to a common ground may cause performance degradation and signal interference due to noise. Therefore, it may be desirable to separate the digital ground 9010 and the analog ground 9020 from each other to prevent the occurrence of noise and signal interference.

The first ground 9010 and the second ground 9020 may be separated from each other, but electrically connected to each other only at a single point by a noise reduction element 9015. Accordingly, the first ground 9010 and the second ground 9020 may provide a common reference potential while minimizing the occurrence of noise and signal interference. The noise reduction element 9015 may include at least one of a zero-ohm resistor and a bead. The bead may be a type of inductor that may block electromagnetic waves or remove or absorb high-frequency noise.

The RF signal generation circuit 210 corresponds to an analog circuit, but processes relatively small power compared to the power conversion circuit, and thus the RF signal generation circuit 210 may be arranged in the first region 910. The charging circuit 120 may be a hybrid circuit that operates in a form in which analog circuits and digital circuits are combined, but since the charging circuit 120 performs the function of controlling voltage and/or current, the charging circuit 120 may be arranged in the second region 920. Accordingly, the RF signal generation circuit 210 may be connected to the first ground 9010, and the charging circuit 120 may be connected to the second ground 9020.

Each of the first power converter 140, the second power converter 150, and the third power converter 160 may be arranged in a manner that does not include opposite facing sides to minimize influences on each other (e.g., transfer of heat, noise, etc.). For example, as illustrated in FIG. 9, the first power converter 140, the second power converter 150, and the third power converter 160 may be arranged so as not to overlap each other along a diagonal line passing through a center of the second region 920, but are not limited thereto.

FIG. 9 may be a diagram illustrating the front surface of the first circuit board 1010 (i.e., a surface in the right direction in the cross-sectional view of FIG. 8). Since a certain amount of heat may be generated during a process of converting power, by a power conversion circuit, the power conversion circuit may be arranged on a surface of the first circuit board 1010, which does not face the heat-sensitive power supply 130. However, the disclosure is not limited thereto.

The second circuit board 1020 may include a third ground 9030 connected to at least one amplifier (e.g., the drive amplifier 220 and/or the power amplifier 230). The third ground 9030 may be directly connected to the second ground 9020, but connected to the first ground 9010 through a noise reduction element (e.g., the noise reduction element 9015). The third ground 9030 and the second ground 9020 being directly connected to each other may indicate that they are connected to each other without using a noise reduction element. As the second ground 9020 and the third ground 9030 are directly connected to each other, they may be viewed as the same ground. The second ground 9020 and the third ground 9030 may be electrically connected to the first ground 9010 only through the noise reduction element 9015.

The second circuit board 1020 may further include the directional coupler 240 that separately receives an amplified RF signal and reflected electromagnetic waves reflected from the insertion space after being radiated by a radiating unit (e.g., the radiating unit 30 of FIGS. 1 and 8). In order for the directional coupler 240 to accurately detect reflected electromagnetic waves corresponding to relatively small signals, the directional coupler 240 may be arranged as far away as possible from at least one amplifier that outputs relatively large signals.

The directional coupler 240 and at least one amplifier may be positioned close to two edges or corners that are opposite to each other with respect to the center of the second circuit board 1020, among the edges or corners of the second circuit board 1020. For example, as illustrated in FIG. 9, the directional coupler 240 may be positioned close to the left edge of the second circuit board 1020, while the drive amplifier 220 and/or the power amplifier 230 may be positioned close to the right edge of the second circuit board 1020. Here, a circuit element positioned close to an edge or corner may indicate, but is not limited to, that a distance between the circuit element and the edge or corner is shorter than a distance between the circuit element and the center of the second circuit board 1020.

The temperature sensing circuit 250 may be arranged adjacent to the power amplifier 230. The temperature sensing circuit 250 may be used to prevent overheating of the second circuit board 1020. The most heat may be generated from the power amplifier 230 on the second circuit board 1020. Thus, the temperature sensing circuit 250 may be arranged as close as possible to the power amplifier 230 to sensitively measure a temperature change of the second circuit board 1020. The processor 170 may stop operation of at least one of the RF signal generation circuit 210 and the at least one amplifier in response to determining that the temperature measured by the temperature sensing circuit 250 exceeds a preset threshold. Accordingly, overheating of the second circuit board 1020 may be prevented.

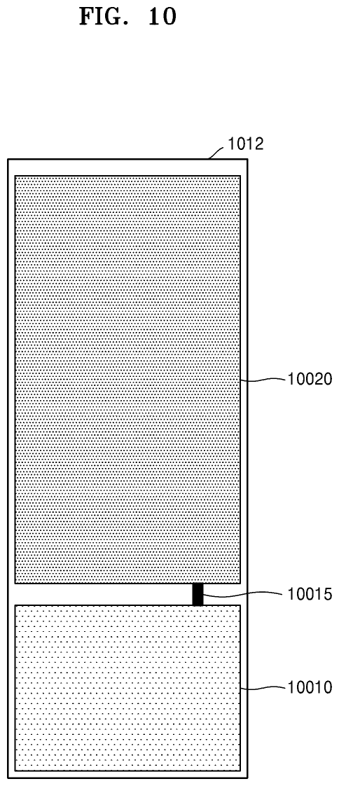

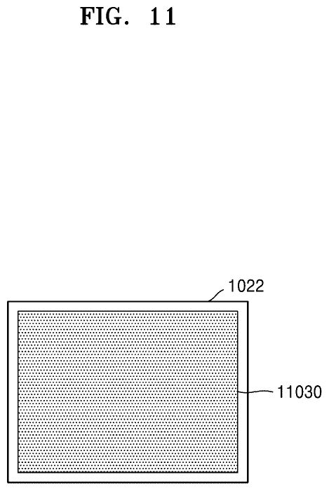

The first circuit board 1010 and/or the second circuit board 1020 may be a double-sided circuit board or a multilayer circuit board. When the first circuit board 1010 and/or the second circuit board 1020 are multilayer circuit boards, the first circuit board 1010 and/or the second circuit board 1020 may include one or more inner layers (e.g., a ground layer) in addition to the double sides thereof. When the first circuit board 1010 and/or the second circuit board 1020 are multilayer circuit boards including at least one ground layer therein, the first ground 9010, the second ground 9020, and/or the third ground 9030 may also be formed in at least one ground layer. Referring to FIGS. 10 and 11, a description will be given of a case where the first circuit board 1010 and/or the second circuit board 1020 are multilayer circuit boards.

FIG. 10 is a diagram illustrating a ground layer of a first circuit board according to an embodiment.

Referring to FIG. 10, a ground layer 1012 inside the first circuit board 1010 is illustrated. The first ground 10010 and the second ground 10020 may each be arranged in physically separated areas within the ground layer 1012. For example, the first ground 10010 may be arranged at a location corresponding to an area (e.g., the first region 910 of FIG. 9) where a digital circuit including the processor 170 is mounted on the front surface of the first circuit board 1010. Additionally, the second ground 10020 may be arranged at a location corresponding to an area (e.g., the second region 920 of FIG. 9) where an analog circuit including at least one power conversion circuit (e.g., the first power converter 140, the second power converter 150, and the third power converter 160) is mounted on the front surface of the first circuit board 1010 and/or an area where the second circuit board 1020 is mounted.

Circuit elements mounted on the front surface of the first circuit board 1010 may be connected to the first ground 10010 or the second ground 10020 through a connecting means such as a via. For example, the processor 170 and the RF signal generation circuit 210 may be connected to the first ground 10010, and the charging circuit 120, the first power converter 140, the second power converter 150, and the third power converter 160 may be connected to the second ground 10020. In an example, the drive amplifier 220, the power amplifier 230, and the temperature sensing circuit 250 mounted on the second circuit board 1020 may also be connected to the second ground 10020.

Meanwhile, since the larger the area of the ground, the better, in FIG. 10, the shapes of the first ground 10010 and the second ground 10020 are illustrated in a simplified manner, but if an element sensitive to heat or noise generated from the ground is arranged on at least one of both sides of the first circuit board 1010 and/or the second circuit board 1020, the ground may not be formed at a position corresponding to (e.g., overlapping) the area where the element is arranged. Additionally, the area of the second ground 10020 may be larger than the area of the first ground 10010.

The first ground 10010 and the second ground 10020 may be electrically connected to each other at only a single point by a noise reduction element 10015 to provide a common reference potential while minimizing the occurrence of noise and signal interference. The noise reduction element 10015 may include at least one of a zero-ohm resistor and a bead. The bead may be a type of inductor that may block electromagnetic waves or remove or absorb high-frequency noise.

FIG. 11 is a diagram illustrating a ground layer of a second circuit board according to an embodiment.

Referring to FIG. 11, the ground layer 1022 inside the second circuit board 1020 is illustrated. A third ground 11030 may be formed in the ground layer 1022. The third ground 11030 may be arranged at a location corresponding to an area on the front surface of the second circuit board 1020 where at least one amplifier (e.g., the drive amplifier 220 and/or the power amplifier 230) is mounted.

At least one amplifier mounted on the front surface of the second circuit board 1020 may be connected to the third ground 11030 through a connecting means such as a via. Accordingly, a first ground (e.g., the first ground 9010 of FIG. 9 or the first ground 10010 of FIG. 10) connected to an RF signal generation circuit (e.g., the RF signal generation circuit 210 of FIG. 1 and FIG. 9) and the third ground 11030 connected to at least one amplifier may be separated. Although both the RF signal generation circuit and the at least one amplifier correspond to analog circuits, considering that the at least one amplifier uses much larger power (e.g., voltage and/or current) than the RF signal generation circuit, the first ground to which the RF signal generation circuit is connected may be separated from the third ground 11030 connected to the at least one amplifier, in order to ensure stable operation of the RF signal generation circuit. The first ground and the third ground 11030 may be electrically connected to each other at a single point by a noise reduction element (e.g., the noise reduction element 9015 of FIG. 9 or the noise reduction element 10015 of FIG. 10). The noise reduction element may include at least one of a zero-ohm resistor and a bead. The bead may be a type of inductor that may block electromagnetic waves or remove or absorb high-frequency noise.

Meanwhile, since the larger the area of the ground, the better, in FIG. 11, the shape of the third ground 11030 is illustrated in a simplified manner, but if an element sensitive to heat or noise generated from the ground is arranged on at least one of both sides of the second circuit board 1020, the ground may not be formed at a location corresponding to (e.g., overlapping) the area where the element is arranged.

An example in which a ground is formed on the front surfaces of the first circuit board 1010 and the second circuit board 1020 is described with reference to FIG. 9, an example in which a ground is formed on the ground layer 1012 of the first circuit board 1010 is described with reference to FIG. 10, and an example in which a ground is formed on the ground layer 1022 of the second circuit board 1020 is described with reference to FIG. 11. However, the ground may be formed on a plurality of surfaces and/or layers among both surfaces and at least one ground layer of the first circuit board 1010 and/or the second circuit board 1020. In this case, first grounds (e.g., the first ground 9010 and the first ground 10010) formed on different layers or surfaces may be connected to each other, and second and/or third grounds (e.g., the second ground 9020, the third ground 9030, the second ground 10020, and the third ground 11030) formed on different layers or surfaces may be connected to each other. However, the connection between the first grounds and the second and/or third grounds be formed by a noise reduction element (e.g., the noise reduction element 9015 of FIG. 9 or the noise reduction element 10015 of FIG. 10) only in one of the plurality of surfaces and/or layers.

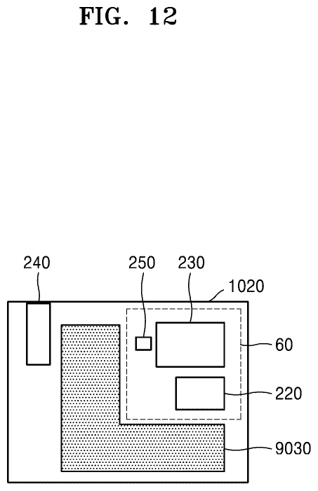

FIG. 12 is a diagram for describing a shielding part according to an embodiment.

Referring to FIG. 12, the second circuit board 1020 may include a shielding part 60 arranged to surround at least one amplifier (e.g., the drive amplifier 220 and/or the power amplifier 230) on the second circuit board 1020. The shielding part 60 may protect circuit elements sensitive to electromagnetic interference (EMI) by preventing emission, to the outside, of electromagnetic waves generated from at least one amplifier.

The shielding part 60 may include at least one of a metal shielding cap (or cover), a shielding plate, and EMI shielding foam. The metal shielding cap (or cover) is a metal cap (or cover) that surrounds a circuit element and may include a metal such as aluminum, copper, or iron. The metal shielding cap (or cover) may be designed to cover an upper end of at least one amplifier and wrap around the sides thereof. The shielding plate may have a planar structure that is arranged on the second circuit board 1020 and covers at least one amplifier. The EMI shielding foam may be used to wrap at least one amplifier in a soft, flexible way by using conductive foam. The shielding part 60 may be connected to the third ground 9030 to strengthen the shielding effect and improve the stability of the entire circuit board.

As described with reference to FIGS. 9 to 12, according to the aerosol generating device 1 of the disclosure, circuit elements mounted within a same circuit board may be arranged in an appropriate manner in consideration of each operating condition and/or operating characteristic. Accordingly, stable operation of circuit elements implementing dielectric heating may be ensured.

Some embodiments or other embodiments of the disclosure described above are not exclusive or distinct from each other. In some embodiments or other embodiments of the disclosure described above, respective components or functions may be used in combination with one another or combined with one another.

For example, a component A described in a particular embodiment and/or drawing and a component B described in another embodiment and/or drawing may be combined with each other. In other words, even when coupling between components is not directly described, the coupling may be made except when the coupling is described as impossible.

The above description should not be construed as being limited in all respects but should be considered illustrative. The scope of the disclosure should be determined by the logical interpretation of appended claims, and all changes within the equivalent scope of the disclosure are included in the scope of the disclosure.

An aerosol generating device according to various embodiments may include a circuit board having mounted thereon circuit elements for controlling the overall operation of the aerosol generating device, and a circuit board having mounted thereon circuit elements for generating and/or amplifying an RF signal. In other words, according to the aerosol generating device, circuit elements corresponding to respective functions may be appropriately distributed to a circuit board more suitable for implementing each function by distinguishing circuit elements by function and mounting the circuit elements on different circuit boards. Additionally, circuit elements mounted within a same circuit board may be arranged in an appropriate manner considering each operating condition and/or operating characteristic. Accordingly, stable operation of circuit elements implementing dielectric heating may be ensured.

The aerosol generating device according to various embodiments may include circuit elements for generating and/or amplifying an RF signal, in addition to the circuit elements for controlling the overall operation of the aerosol generating device. The circuit elements for amplifying RF signals process high-frequency and/or high-power signals, and thus, the circuit elements may be mounted on a circuit board manufactured from materials optimized for high-frequency and high-speed signal transmission. However, the circuit boards manufactured from materials optimized for high-frequency and high-speed signal transmission are more expensive than typical circuit boards, and thus, it may be inefficient to mount all circuit elements on such circuit boards. According to the aerosol generating device of the disclosure, normal operation of each circuit element may be ensured without significantly increasing manufacturing costs by mounting the circuit elements on different circuit boards by distinguishing the circuit elements according to operating conditions and/or operating characteristics.

According to the aerosol generating device of the disclosure, mass production and low cost may be achieved through an automated assembly process along with miniaturization of an entire circuit board portion by directly mounting another circuit board on a surface of one circuit board using SMT.

In addition, circuit elements mounted within a same circuit board may be arranged in an appropriate manner considering each operating condition and/or operating characteristic. Accordingly, stable operation of circuit elements implementing dielectric heating may be ensured.

Problems to be solved through embodiments of the disclosure are not limited to the above-described problems, and problems not mentioned may be clearly understood by one of ordinary skill in the art to which the embodiments belong from the description and accompanying drawings.

What is claimed is:

1. An aerosol generating device comprising:
a power supply;
a first circuit board on which a processor is mounted;
a second circuit board, which is arranged spaced apart from the first circuit board and has mounted thereon a radio frequency (RF) signal generation circuit configured to generate an RF signal by using power supplied from the power supply and at least one amplifier configured to amplify the generated RF signal; and
a radiating unit configured to heat an aerosol-generating article by radiating the amplified RF signal in the form of electromagnetic waves into an insertion space into which the aerosol-generating article is inserted,
wherein the processor is configured to control the RF signal generation circuit and the at least one amplifier.

2. The aerosol generating device of claim 1, wherein a first region in which the RF signal generation circuit is mounted and a second region in which the at least one amplifier is mounted are physically separated from each other within the second circuit board.

3. The aerosol generating device of claim 1, wherein the RF signal generation circuit and the at least one amplifier are respectively positioned close to, from among edges or corners of the second circuit board, two edges or corners of the second circuit board, the two edges or corners being opposite each other with respect to a center of the second circuit board.

4. The aerosol generating device of claim 1, wherein the second circuit board comprises a first ground connected to the RF signal generation circuit and a second ground disposed separately from the first ground and connected to the at least one amplifier, and
the first ground and the second ground are electrically connected to each other at a single point by a noise reduction element.

5. The aerosol generating device of claim 4, wherein the noise reduction element comprises at least one of a zero-ohm resistor and a bead.

6. The aerosol generating device of claim 4, wherein the first ground and the second ground are respectively disposed in physically separated areas within at least one ground layer, when the second circuit board comprises a multilayer circuit board including the at least one ground layer therein.

7. The aerosol generating device of claim 1, wherein the at least one amplifier comprises a drive amplifier configured to amplify a level of the generated RF signal, and a power amplifier configured to amplify power of the RF signal received from the drive amplifier.

8. The aerosol generating device of claim 7, further comprising a temperature sensing circuit mounted on the second circuit board,
wherein the temperature sensing circuit is positioned adjacent to the power amplifier.

9. The aerosol generating device of claim 8, wherein the processor is further configured to stop operation of at least one of the RF signal generation circuit and the at least one amplifier in response to determining that a temperature measured by the temperature sensing circuit exceeds a preset threshold value.

10. The aerosol generating device of claim 1, further comprising a heat dissipation unit configured to effectively dissipate or disperse heat generated from the second circuit board to minimize transfer of heat generated from the second circuit board to the power supply.

11. The aerosol generating device of claim 10, wherein the second circuit board is positioned so as not to overlap the power supply in any of left-right, front-back, and up-down directions, and
the heat dissipation unit is arranged in contact with or adjacent to at least one surface of the second circuit board.

12. The aerosol generating device of claim 1, further comprising a directional coupler configured to separately receive the amplified RF signal and reflected electromagnetic waves radiated by the radiating unit and then reflected from the insertion space.

13. The aerosol generating device of claim 12, wherein the directional coupler and the at least one amplifier are respectively positioned close to two edges or corners which are opposite to each other with respect to a center of the second circuit board among edges or corners of the second circuit board.

14. The aerosol generating device of claim 12, wherein the directional coupler and the at least one amplifier are disposed on different surfaces of the second circuit board.

15. The aerosol generating device of claim 1, further comprising at least one power conversion circuit mounted on the first circuit board and configured to convert power supplied from the power supply into power suitable for each of the processor, the RF signal generation circuit, and the at least one amplifier,
wherein an area in which a digital circuit including the processor is mounted and an area in which an analog circuit including the at least one power conversion circuit is mounted are electrically and physically separated from each other within the first circuit board.
